(19) United States
(12) Patent Application Publication
(10) Pub. No.: US 2025/0301647 A1
(43) Pub. Date: Sep. 25, 2025

(54) SEMICONDUCTOR MEMORY DEVICE

(71) Applicant: Kioxia Corporation, Tokyo (JP)

(72) Inventors: Eri SAHARA, Nagoya (JP); Wataru HASEGAWA, Yokkaichi (JP); Takuya KONNO, Yokkaichi (JP)

(73) Assignee: Kioxia Corporation, Tokyo (JP)

(21) Appl. No.: 19/065,168

(22) Filed: Feb. 27, 2025

(30) Foreign Application Priority Data
Mar. 19, 2024 (JP) 2024-043719

(51) Int. Cl. H10B 43/27

(52) U.S. Cl. CPC H10B 43/27

(57) ABSTRACT

A semiconductor memory device of an embodiment includes: a stacked body in which a plurality of conductive layers and a plurality of insulating layers are alternately stacked; a pillar that includes a channel layer extending through the stacked body in a stacking direction of the stacked body; a contact that is provided in a region of the stacked body different from a disposition region of the pillar and connected to one conductive layer of the plurality of conductive layers; and a plurality of columnar portions that is provided to be spaced apart a predetermined distance from the contact so as to surround the contact and extends through the stacked body in the stacking direction, wherein an insulating layer of the plurality of insulating layers located in a region including the contact and surrounded by the plurality of columnar portions has, in at least a portion, at least one selected from the group consisting of a higher Young's modulus, a lower compressive stress, and a higher tensile stress than an insulating layer in the disposition region of the pillar.

### CROSS-REFERENCE TO RELATED APPLICATIONS

This application is based upon and claims the benefit of priority from Japanese Patent Application No. 2024-043719, filed on Mar. 19, 2024; the entire contents of which are incorporated herein by reference.

### FIELD

Embodiments described herein relate generally to a semiconductor memory device.

### BACKGROUND

In a semiconductor memory device such as a three-dimensional nonvolatile memory, a treatment of stacking a plurality of sacrificial layers and replacing the sacrificial layers with a plurality of conductive layers may be performed. At this time, there is a concern that a plurality of insulating layers interposed between the plurality of sacrificial layers is bent.

### BRIEF DESCRIPTION OF THE DRAWINGS

FIG. 1 is a cross-sectional view illustrating a schematic configuration example of a semiconductor memory device according to a first embodiment;

FIGS. 2A to 2C are views illustrating an example of a configuration of the semiconductor memory device according to the first embodiment;

FIG. 3 is a view illustrating an example of a configuration of the semiconductor memory device according to the first embodiment;

FIGS. 4A to 4C are views sequentially illustrating a part of a procedure of a method for manufacturing the semiconductor memory device according to the first embodiment;

FIGS. 5A and 5B are views sequentially illustrating a part of a procedure of the method for manufacturing the semiconductor memory device according to the first embodiment;

FIGS. 6A and 6B are views sequentially illustrating a part of a procedure of the method for manufacturing the semiconductor memory device according to the first embodiment;

FIGS. 7A and 7B are views sequentially illustrating a part of a procedure of the method for manufacturing the semiconductor memory device according to the first embodiment;

FIGS. 8A and 8B are views sequentially illustrating a part of a procedure of the method for manufacturing the semiconductor memory device according to the first embodiment;

FIGS. 9A and 9B are views sequentially illustrating a part of a procedure of the method for manufacturing the semiconductor memory device according to the first embodiment;

FIGS. 10A to 10C are views sequentially illustrating a part of a procedure of the method for manufacturing the semiconductor memory device according to the first embodiment;

FIGS. 11A to 11C are views sequentially illustrating a part of a procedure of the method for manufacturing the semiconductor memory device according to the first embodiment;

FIGS. 12A to 12C are views sequentially illustrating a part of a procedure of the method for manufacturing the semiconductor memory device according to the first embodiment;

FIGS. 13A and 13B are views sequentially illustrating a part of a procedure of the method for manufacturing the semiconductor memory device according to the first embodiment;

FIGS. 14A and 14B are views sequentially illustrating a part of a procedure of the method for manufacturing the semiconductor memory device according to the first embodiment;

FIGS. 15A and 15B are views sequentially illustrating a part of a procedure of the method for manufacturing the semiconductor memory device according to the first embodiment;

FIGS. 16A and 16B are views sequentially illustrating a part of a procedure of the method for manufacturing the semiconductor memory device according to the first embodiment;

FIGS. 17A and 17B are views sequentially illustrating a part of a procedure of the method for manufacturing the semiconductor memory device according to the first embodiment;

FIG. 18 is a cross-sectional view along an X direction illustrating an example of a configuration of a semiconductor memory device according to a first modification of the first embodiment;

FIGS. 19A and 19B are cross-sectional views sequentially illustrating a part of a procedure of a method for manufacturing the semiconductor memory device according to the first modification of the first embodiment;

FIGS. 20A and 20B are cross-sectional views sequentially illustrating a part of a procedure of the method for manufacturing the semiconductor memory device according to the first modification of the first embodiment;

FIG. 21 is a cross-sectional view along an X direction illustrating an example of a configuration of a semiconductor memory device according to a second modification of the first embodiment;

FIGS. 22A and 22B are cross-sectional views illustrating a part of a procedure of a method for manufacturing the semiconductor memory device according to the second modification of the first embodiment;

FIGS. 23A and 23B are cross-sectional views along an X direction illustrating an example of a configuration of a semiconductor memory device according to a second embodiment;

FIGS. 24A and 24B are views sequentially illustrating a part of a procedure of a method for manufacturing the semiconductor memory device according to the second embodiment;

FIGS. 25A and 25B are views sequentially illustrating a part of a procedure of the method for manufacturing the semiconductor memory device according to the second embodiment;

FIGS. 26A and 26B are views sequentially illustrating a part of a procedure of the method for manufacturing the semiconductor memory device according to the second embodiment;

FIGS. 27A and 27B are cross-sectional views along an X direction illustrating an example of a configuration of a semiconductor memory device according to a first modification of the second embodiment;

FIGS. 28A and 28B are views illustrating a part of a procedure of a method for manufacturing the semiconductor memory device according to the first modification of the second embodiment;

FIGS. 29A and 29B are cross-sectional views along an X direction illustrating an example of a configuration of the semiconductor memory device according to the first modification of the second embodiment;

FIGS. 30A and 30B are views illustrating a part of a procedure of a method for manufacturing the semiconductor memory device according to the second modification of the second embodiment;

FIG. 31 is a cross-sectional view along an X direction illustrating an example of a configuration of a semiconductor memory device according to a third modification of the second embodiment; and

FIG. 32 is a cross-sectional view illustrating a schematic configuration example of a semiconductor memory device according to a third embodiment.

FIGS. 33A and 33B are cross-sectional views along an X direction illustrating an example of a configuration of a semiconductor memory device according to a first modification of the third embodiment;

FIGS. 34A to 34D are views sequentially illustrating a part of a procedure of a method for manufacturing the semiconductor memory device according to the first modification of the third embodiment;

FIGS. 35A to 35D are views sequentially illustrating a part of a procedure of the method for manufacturing the semiconductor memory device according to the first modification of the third embodiment;

FIGS. 36A to 36D are views sequentially illustrating a part of a procedure of the method for manufacturing the semiconductor memory device according to the first modification of the third embodiment;

FIGS. 37A to 37D are views sequentially illustrating a part of a procedure of the method for manufacturing the semiconductor memory device according to the first modification of the third embodiment;

FIGS. 38A to 38D are views sequentially illustrating a part of a procedure of the method for manufacturing the semiconductor memory device according to the first modification of the third embodiment;

FIGS. 39A to 39D are views sequentially illustrating a part of a procedure of a method for manufacturing a semiconductor memory device according to a second modification of the third embodiment;

FIGS. 40A and 40B are cross-sectional views along an X direction illustrating an example of a configuration of a semiconductor memory device according to a third modification of the third embodiment; and

FIGS. 41A to 41D are views sequentially illustrating a part of a procedure of a method for manufacturing the semiconductor memory device according to the third modification of the third embodiment.

### DETAILED DESCRIPTION

A semiconductor memory device of an embodiment includes: a stacked body in which a plurality of conductive layers and a plurality of insulating layers are alternately stacked; a pillar that includes a channel layer extending through the stacked body in a stacking direction of the stacked body; a contact that is provided in a region of the stacked body different from a disposition region of the pillar and connected to one conductive layer of the plurality of conductive layers; and a plurality of columnar portions that is provided to be spaced apart a predetermined distance from the contact so as to surround the contact and extends through the stacked body in the stacking direction, wherein an insulating layer of the plurality of insulating layers located in a region including the contact and surrounded by the plurality of columnar portions has, in at least a portion, at least one selected from the group consisting of a higher Young's modulus, a lower compressive stress, and a higher tensile stress than an insulating layer in the disposition region of the pillar.

Hereinafter, embodiments of the present invention will be described in detail with reference to the drawings. Note that the present invention is not limited by the embodiments described below. In addition, constituent elements in the embodiments described below include those that can be easily assumed by those skilled in the art or those that are substantially the same.

### First Embodiment

Hereinafter, a first embodiment will be described in detail with reference to the drawings.

### Configuration Example of Semiconductor Memory Device

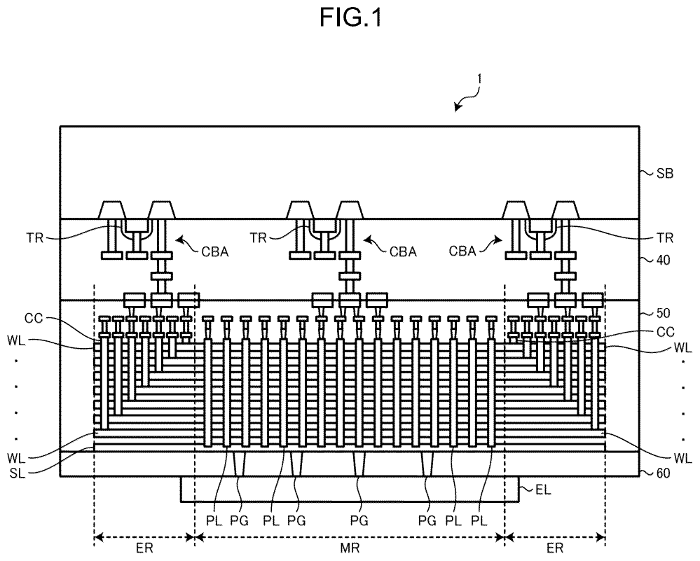

FIG. 1 is a cross-sectional view illustrating a schematic configuration example of a semiconductor memory device 1 according to a first embodiment. However, in FIG. 1, hatching is omitted in consideration of visibility of the drawing.

As illustrated in FIG. 1, the semiconductor memory device 1 includes an electrode film EL, a source line SL, and a plurality of word lines WL in order from the lower side of the drawing. In addition, the semiconductor memory device 1 includes peripheral circuits CBA provided on a semiconductor substrate SB above the plurality of word lines WL.

The source line SL is disposed on the electrode film EL via an insulating layer 60. A plurality of plugs PG is disposed in the insulating layer 60, and the source line SL and the electrode film EL maintain electrical conduction via the plugs PG. As a result, a source potential can be applied to the source line SL from the outside of the semiconductor memory device 1 via the electrode film EL and the plugs PG.

The plurality of word lines WL is stacked on the source line SL. A memory region MR is disposed at central portions of the plurality of word lines WL, and contact regions ER are disposed at both end portions of the plurality of word lines WL.

In the memory region MR, a plurality of pillars PL penetrating the word lines WL in a stacking direction is disposed. A plurality of memory cells is formed at intersection portions of the pillars PL and the word lines WL. As a result, the semiconductor memory device 1 is configured as, for example, a three-dimensional nonvolatile memory in which memory cells are three-dimensionally disposed in the memory region MR.

In the contact regions ER, a plurality of contacts CC respectively connected to the plurality of word lines WL is disposed. Note that, in the present specification, in the extending direction of the contacts CC, a connection end side of the contact CC with the word line WL is defined as a lower side of the semiconductor memory device 1.

A write voltage, a read voltage, and the like are applied from the contacts CC to the memory cells included in the memory region MR at the central portions of the plurality of word lines WL via the word lines WL at the same height positions as the memory cells. In this manner, the word lines WL stacked in multiple layers are individually lead out by these contacts CC.

The plurality of word lines WL, the pillars PL, and the contacts CC are covered with an insulating layer 50. The insulating layer 50 also extends around the plurality of word lines WL.

The semiconductor substrate SB above the insulating layer 50 is, for example, a silicon substrate or the like. The peripheral circuits CBA including transistors TR, wiring, and the like are disposed on the surface of the semiconductor substrate SB. Various voltages applied from the contacts CC to the memory cells are controlled by the peripheral circuits CBA electrically connected to the contacts CC. In this manner, the peripheral circuits CBA control the electrical operation of the memory cells.

The peripheral circuits CBA are covered with an insulating layer 40, and the insulating layer 40 and the insulating layer 50 covering a stacked body LM are joined to form the semiconductor memory device 1 including the configurations of the plurality of word lines WL, the pillars PL, the contacts CC, and the like, and the peripheral circuits CBA.

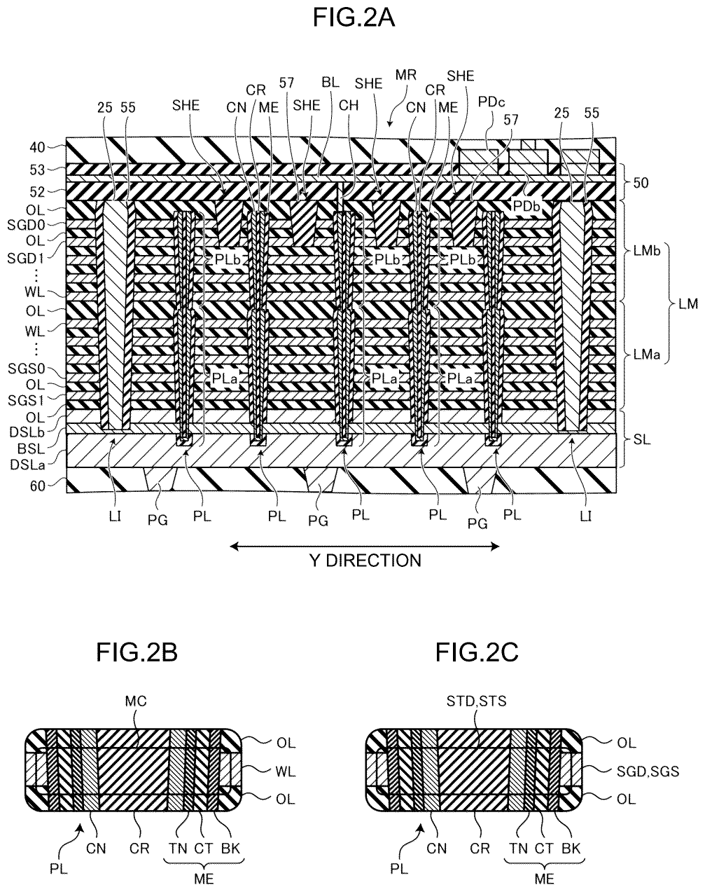

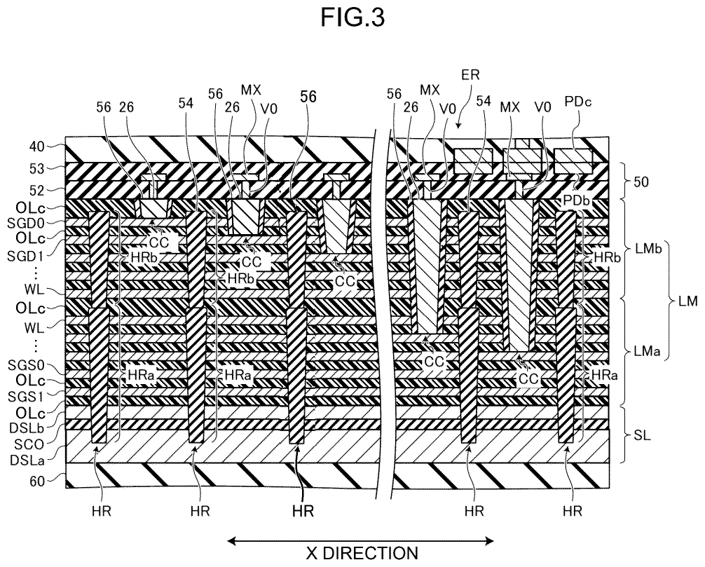

Next, a detailed configuration example of the semiconductor memory device 1 will be described with reference to FIGS. 2A to 3. FIGS. 2A to 3 are views illustrating an example of a configuration of the semiconductor memory device 1 according to the first embodiment.

More specifically, FIG. 2A is a cross-sectional view along a Y direction illustrating an example of the configuration of the memory region MR. FIG. 2B is an enlarged cross-sectional view of the pillar PL disposed in the memory region MR at the height position of the word line WL. FIG. 2C is an enlarged cross-sectional view of the pillar PL disposed in the memory region MR at the height position of a select gate line SGD or SGS.

FIG. 3 is a cross-sectional view along the X direction illustrating an example of the configuration of the contact region ER.

However, in FIGS. 2A and 3, structures below the insulating layer 60 and above the insulating layer 40 are omitted.

Note that, in the present specification, both the X direction and the Y direction are directions along the orientation of the surfaces of the word lines WL, and the X direction and the Y direction are orthogonal to each other. In addition, the electrical lead-out direction of the word lines WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 2A, the source line SL has a multilayer structure in which, for example, a lower source line DSLa, an intermediate source line BSL, and an upper source line DSLb are stacked in this order on the insulating layer 60.

The lower source line DSLa, the intermediate source line BSL, and the upper source line DSLb are, for example, polysilicon layers. Among them, at least the intermediate source line BSL may be a conductive polysilicon layer or the like in which impurities are diffused.

The stacked body LM is disposed on the source line SL. The stacked body LM includes stacked bodies LMa and LMb in which the plurality of word lines WL and a plurality of insulating layers OL are alternately stacked one by one. The stacked body LMa as a first stacked body is disposed above the source line SL, and the stacked body LMb as a second stacked body is disposed on the stacked body LMa.

One or more select gate lines SGS are disposed via the insulating layer OL below the lowermost word line WL of the stacked body LMa. In the example of FIG. 2A, the stacked body LMa includes two select gate lines SGS0 and SGS1 in order from the upper layer side. One or more select gate lines SGD are disposed via the insulating layer OL above the uppermost word line WL of the stacked body LMb. In the example of FIG. 2A, the stacked body LMb includes two select gate lines SGD0 and SGD1 in order from the upper layer side.

However, the number of word lines WL and select gate lines SGD and SGS stacked in the stacked body LM is arbitrary.

The word lines WL and the select gate lines SGD and SGS as the plurality of conductive layers are, for example, a tungsten layer or a molybdenum layer. The plurality of insulating layers OL is, for example, a silicon oxide layer or the like.

The uppermost insulating layer OL of each of the stacked bodies LMa and LMb is thicker than, for example, another insulating layer OL in the stacked bodies LMa and LMb. The uppermost insulating layer OL of the stacked body LMa is in contact with the lowermost word line WL of the stacked body LMb, and insulating layers 52 and 53 are disposed in this order on the uppermost insulating layer OL of the stacked body LMb. The insulating layers 52 and 53 constitute a part of the insulating layer 50 described above, and the upper surface of the insulating layer 53 is in contact with, for example, the lower surface of the insulating layer 40 on the peripheral circuit CBA side.

In addition, the stacked body LM is divided in the Y direction by a plurality of plate-like contacts LI.

That is, the plate-like contacts LI are each arranged in the Y direction and extend in the stacking direction of the stacked body LM and in a direction along the X direction. As described above, the plate-like contacts LI continuously extend in the stacked body LM from one end portion to the other end portion of the stacked body LM in the X direction. In addition, the plate-like contacts LI penetrate the stacked body LM and the upper source line DSLb and reach the intermediate source line BSL.

In addition, each of the plate-like contacts LI includes an insulating layer 55 and a conductive layer 25. The insulating layer 55 is, for example, a silicon oxide layer or the like. The conductive layer 25 is, for example, a tungsten layer or a conductive polysilicon layer.

The insulating layer 55 covers the side walls of the plate-like contact LI facing each other in the Y direction. The conductive layer 25 is loaded inside the insulating layer 55, and electrically connected to the source line SL including the intermediate source line BSL. In addition, the conductive layer 25 is connected to upper wiring in a cross section different from that in FIG. 2A. With such a configuration, the plate-like contact LI functions as a source line contact.

However, instead of the plate-like contact LI, a plate-like member filled with the insulating layer may penetrate the stacked body LM and extend in the direction along the X direction, thereby dividing the stacked body LM in the Y direction. In this case, such a plate-like member does not have a function as a source line contact.

A plurality of separation layers SHE is disposed between the plate-like contacts LI adjacent in the Y direction. These separation layers SHE are insulating layers 57 such as silicon oxide layers that penetrate the select gate lines SGD0 and SGD1 of the stacked body LMb, reach the insulating layer OL immediately below the select gate line SGD1, and extend in the memory region MR of the stacked body LM in a direction along the X direction. With such a configuration, the separation layers SHE selectively separate the select gate lines SGD0 and SGD1 between the plate-like contacts LI in the Y direction.

In the memory region MR of the stacked body LM, the plurality of pillars PL penetrating the stacked body LM, the upper source line DSLb, and the intermediate source line BSL and reaching the lower source line DSLa is dispersedly disposed.

The plurality of pillars PL is disposed, for example, periodically in a staggered manner when viewed from the stacking direction of the stacked body LM. Each pillar PL has, for example, a circular shape, an elliptical shape, an oblong shape (oval shape), or the like as a cross-sectional shape in a direction along the layering direction of the stacked body LM, that is, in a direction along the XY plane.

The pillar PL includes a pillar PLa that penetrates the stacked body LMa from the uppermost insulating layer OL of the stacked body LMa and reaches the source line SL, and a pillar PLb that penetrates the stacked body LMb from the uppermost insulating layer OL of the stacked body LMb, reaches the uppermost insulating layer OL of the stacked body LMa, and is connected to an upper end portion of the corresponding pillar PLa.

Each of the plurality of pillars PL includes a memory layer ME extending in the stacked body LM in the stacking direction, a channel layer CN penetrating the stacked body LM and connected to the intermediate source line BSL, and a core layer CR serving as a core material of the pillar PL.

The memory layer ME is disposed on a side surface of the pillar PL except for the depth position of the intermediate source line BSL. In addition, the memory layer ME is also disposed on the bottom surface of the pillar PL reaching the depth of the lower source line DSLa.

The channel layer CN penetrates the stacked body LM, the upper source line DSLb, and the intermediate source line BSL inside the memory layer ME and reaches the depth of the lower source line DSLa. That is, the channel layer CN is disposed on the side surface and the bottom surface of the pillar PL via the memory layer ME. The core layer CR is loaded further inside the channel layer CN.

However, a part of the channel layer CN is, on a side surface, in contact with the intermediate source line BSL, so that the channel layer CN is electrically connected to the source line SL including the intermediate source line BSL. In addition, an upper end portion of the channel layer CN is connected to a bit line BL extending in a direction along the Y direction in the insulating layer 53 via a plug CH disposed in the insulating layer 52.

As illustrated in FIGS. 2B and 2C, the memory layer ME has a multilayer structure in which a block insulating layer BK, a charge storage layer CT, and a tunnel insulating layer TN are stacked in this order from the outer peripheral side of the pillar PL.

The block insulating layer BK and the tunnel insulating layer TN of the memory layer ME, and the core layer CR are, for example, silicon oxide layers or the like. The charge storage layer CT of the memory layer ME is, for example, a silicon nitride layer or the like. The channel layer CN is a semiconductor layer such as a polysilicon layer or an amorphous silicon layer.

As illustrated in FIG. 2B, with the above configuration, memory cells MC are formed in portions facing the individual word lines WL on the side surface of the pillar PL. When a predetermined voltage is applied from the word line WL, data is written to and read from the memory cell MC.

Data from the memory cell MC is read out to the bit line BL connected to the pillar PL. The bit line BL is connected to an electrode pad PDb disposed on the surface of the insulating layer 53. The electrode pad PDb is disposed on the surface of the insulating layer 40 and is connected to an electrode pad PDc electrically connected to the peripheral circuits CBA. As a result, the data of the memory cell MC read out to the bit line BL is processed by the peripheral circuits CBA.

As illustrated in FIG. 2C, with the above configuration, select gates STD are formed in portions facing the individual select gate lines SGD on the side surface of the pillar PL. In addition, select gates STS are formed in portions facing the individual select gate lines SGS on the side surface of the pillar PL. When predetermined voltages are applied from the select gate lines SGD and SGS, the select gates STD and STS are turned on or off, and the memory cells MC formed in the pillar PL to which the select gates STD and STS belong are brought into a selected state or a non-selected state.

As illustrated in FIG. 3, in the contact region ER, the source line SL includes an intermediate insulating layer SCO between the lower source line DSLa and the upper source line DSLb instead of the intermediate source line BSL. This is because the pillar PL to be connected with the source line SL is not disposed in the contact region ER. The intermediate insulating layer SCO is, for example, a silicon oxide layer or the like. However, the source line SL may include the intermediate source line BSL also in the contact region ER.

In addition, in the contact region ER, a plurality of insulating layers OLc having at least one of a higher Young's modulus, a lower compressive stress, and a higher tensile stress than the plurality of insulating layers OL in the memory region MR is disposed in the stacked body LM. As will be described below, these insulating layers OLc are formed by forming the plurality of insulating layers OL extending over the memory region MR and the contact region ER and then ion-implanting at least one of carbon and nitrogen into the insulating layers OL of the contact region ER, for example.

That is, both the insulating layers OL and OLc of the memory region MR and the contact region ER are, for example, silicon oxide layers, and the insulating layers OLc of the contact region ER contain, for example, at least one of carbon and nitrogen as a dopant. Note that when carbon is contained in the insulating layers OLc, the concentration of carbon is preferably, for example, 0.5 atom % or more, more preferably 1.5 atom % or more.

In addition, in the contact region ER, the plurality of contacts CC and a plurality of columnar portions HR are disposed.

The contacts CC as first contacts extend in the stacked body LMb in the stacking direction of the stacked body LM and are connected to one or more select gate lines SGD or any of the plurality of word lines WL included in the stacked body LMb.

The contacts CC as second contacts extend in the stacked bodies LMa and LMb in the stacking direction of the stacked body LM and are connected to any of the plurality of word lines WL included in the stacked body LMa. In addition, although not illustrated, the contacts CC as second contacts are also connected to one or more select gate lines SGS of the stacked body LMa.

The upper end portions of these contacts CC are disposed, for example, in the uppermost insulating layer OLc of the stacked body LMb. In addition, the lower end portions of these contacts CC reach connection target word lines WL or select gate lines SGD and SGS.

In addition, the contact CC includes an insulating layer 56 covering the outer periphery of the contact CC, and a conductive layer 26 such as a tungsten layer or a copper layer loaded inside the insulating layer 56.

The conductive layer 26 of the contact CC is connected to upper wiring MX disposed in the insulating layer 53 via a plug V0 disposed in the insulating layer 52. The upper wiring MX is electrically connected to the above-described peripheral circuits CBA (see FIG. 1) via the electrode pad PDb on the surface of the insulating layer 53, the electrode pad PDc on the surface of the insulating layer 40, and the like.

Note that, in the region sandwiched by the plate-like contacts LI, the above-described plurality of separation layers SHE extends in the direction along the X direction in the memory region MR between the plate-like contacts LI, and also extends in the direction along the X direction in a portion of the contact region ER where the plurality of contacts CC connected to the select gate lines SGD is disposed.

As a result, the select gate lines SGD are sandwiched between the plate-like contact LI and the separation layer SHE or the two separation layers SHE on both sides in the Y direction, and the end portion in the X direction is selectively separated into a plurality of regions separated by the separation layers SHE. The contact CC is connected to each of a plurality of regions of the select gate lines SGD separated by the plate-like contacts LI and the separation layers SHE.

With such a configuration, the word lines WL and the select gate lines SGD and SGS of the layers can be electrically lead out.

That is, with the above configuration, a predetermined voltage can be applied from the peripheral circuits CBA to the memory cells MC via the upper wiring MX, the contacts CC, and the word lines WL to operate the memory cells MC as a storage element.

In addition, a predetermined voltage is applied from the peripheral circuits CBA to the select gates STD and STS via the upper wiring MX, the contacts CC, and the select gate lines SGD and SGS, and the memory cells MC can be brought into a selected state or a non-selected state. At this time, the memory cell MC is brought into a selected state or a non-selected state for each region separated by the plate-like contacts LI and the separation layers SHE.

In the contact region ER in which the plurality of contacts CC is disposed, the plurality of columnar portions HR penetrating the stacked body LM, the upper source line DSLb, and the intermediate insulating layer SCO and reaching the lower source line DSLa is dispersedly disposed.

The plurality of columnar portions HR is disposed, for example, substantially periodically in a grid shape or a staggered manner when viewed from the stacking direction of the stacked body LM. The reason why the disposition of the plurality of columnar portions HR is substantially periodic is that since the columnar portions HR are disposed while avoiding interference with the plurality of contacts CC and the plate-like contacts LI, the periodicity of the disposition of the columnar portions HR is slightly lost around the plurality of contacts CC and the plate-like contacts LI.

Each of the columnar portions HR has, for example, a circular shape, an elliptical shape, an oval shape, or the like as a cross-sectional shape in a direction along the XY plane.

Each of the columnar portions HR includes a columnar portion HRa that penetrates the stacked body LMa from the uppermost insulating layer OLc of the stacked body LMa and reaches the source line SL, and a columnar portion HRb that penetrates the stacked body LMb from the uppermost insulating layer OLc of the stacked body LMb, reaches the uppermost insulating layer OLc of the stacked body LMa, and is connected to an upper end portion of the corresponding columnar portion HRa.

As will be described below, these columnar portions HR are dummy pillars having, when forming the stacked body LM from the stacked body in which the sacrificial layer and the insulating layer are stacked, a role of supporting these configurations, and not contributing to the function of the semiconductor memory device 1. Therefore, each of the columnar portions HRa and HRb is configured solely by the insulating layer 54 such as a silicon oxide layer, and is configured such that the columnar portions HR do not electrically affect other configurations.

In addition, at the same height position of the stacked body LM, the cross-sectional area of the columnar portion HR in the direction along the XY plane may be larger than, for example, the cross-sectional area of the pillar PL in the direction along the XY plane. In addition, the pitch between the plurality of columnar portions HR may be larger than, for example, the pitch between the plurality of pillars PL. In the XY plane, the disposition density of the columnar portions HR per unit area of the word line WL in the stacked body LM may be lower than the disposition density of the pillars PL per unit area of the word line WL.

As described above, for example, by configuring the cross-sectional area of the pillar PL to be smaller and having a narrower pitch than that of the columnar portion HR, a large number of memory cells MC can be formed at a high density in the stacked body IM having a predetermined size, and the storage capacity of the semiconductor memory device 1 can be increased. On the other hand, since the columnar portions HR are exclusively used to support the stacked body LM, it is possible to reduce the manufacturing load of the semiconductor memory device 1 by not having a precise configuration with a small cross-sectional area and a narrow pitch like the pillars PL, for example.

### (Method for Manufacturing Semiconductor Memory Device)

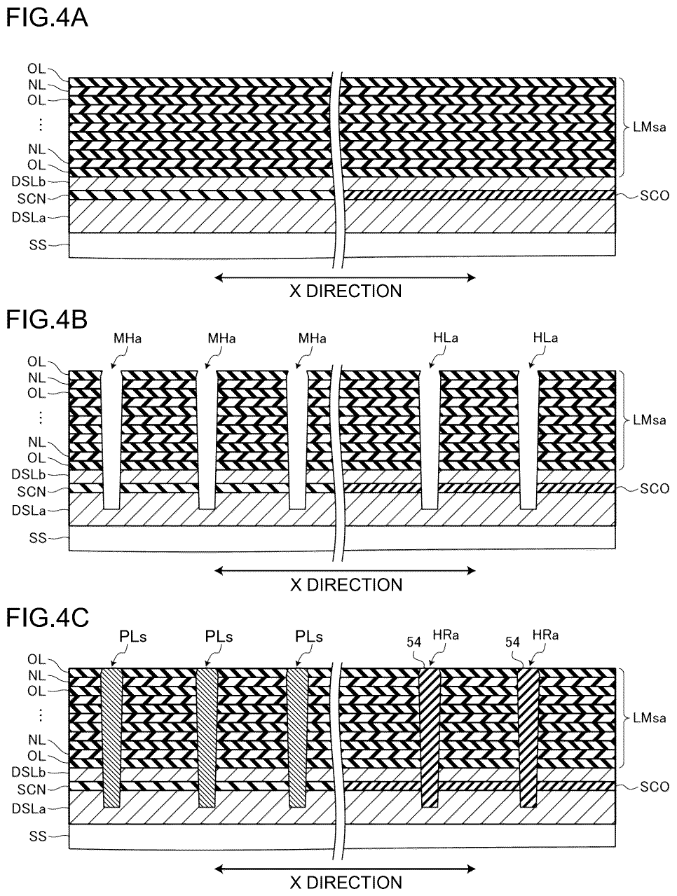

Next, a method for manufacturing the semiconductor memory device 1 of the first embodiment will be described with reference to FIGS. 4A to 17B. FIGS. 4A to 17B are views sequentially illustrating a part of a procedure of the method for manufacturing the semiconductor memory device 1 according to the first embodiment.

First, FIGS. 4A to 4C illustrate a state in which a configuration to be a part of the pillars PL and the columnar portions HR is formed later. FIGS. 4A to 4C illustrate a cross section along the X direction of the semiconductor memory device 1 in the middle of manufacturing, including a region that later becomes the memory region MR and a region that later becomes the contact region ER.

As illustrated in FIG. 4A, the lower source line DSLa, an intermediate sacrificial layer SCN or the intermediate insulating layer SCO, and the upper source line DSLb are formed in this order on a support substrate SS.

The support substrate SS may be, for example, a semiconductor substrate such as a silicon substrate, an insulating substrate such as a ceramic substrate or a quartz substrate, a conductive substrate, or the like.

The lower source line DSLa and the upper source line DSLb are, for example, polysilicon layers. The intermediate sacrificial layer SCN is a layer that is later replaced with a polysilicon layer or the like and becomes the intermediate source line BSL, and is disposed in a region that later becomes the memory region MR. The intermediate insulating layer SCO is, for example, a silicon oxide layer or the like, and is disposed in a region that later becomes the contact region ER.

A stacked body LMsa in which a plurality of insulating layers NL and the plurality of insulating layers OL are alternately stacked one by one is formed on the upper source line DSLb. The insulating layers NL are, for example, silicon nitride layers or the like, and function as sacrificial layers that are replaced with conductive materials that later become the word lines WL or the select gate lines SGS. The stacked body LMsa is a portion that becomes the stacked body LMa later by such replacing treatment.

Note that, at this stage, the plurality of insulating layers OL including the uppermost insulating layer OL may have substantially the same thickness.

As illustrated in FIG. 4B, a plurality of memory holes MHa penetrating the stacked body LMsa, the upper source line DSLb, and the intermediate sacrificial layer SCN and reaching the lower source line DSLa is formed in a region that later becomes the memory region MR. In addition, a plurality of holes HLa penetrating the stacked body LMsa, the upper source line DSLb, and the intermediate insulating layer SCO and reaching the lower source line DSLa is formed in a region that later becomes the contact region ER.

The memory holes MHa and the holes HLa can be collectively formed, for example. However, the memory holes MHa and the holes HLa may be individually formed. In this case, when the memory holes MHa are formed, the region that later becomes the contact region ER can be protected with a resist layer or the like. In addition, when the holes HLa are formed, the region that later becomes the memory region MR can be protected with a resist layer or the like.

As illustrated in FIG. 4C, the memory holes MHa are filled with sacrificial layers such as amorphous silicon layers to form a plurality of pillars PLs. In addition, the holes HLa are filled with the insulating layers 54 such as silicon oxide layers, for example, to form the plurality of columnar portions HRa.

The pillars PLs and the columnar portions HRa are individually formed. In this case, when the pillars PLS are formed, the region that later becomes the contact region ER can be protected with a resist layer or the like. In addition, when the columnar portions HRa are formed, the region that later becomes the memory region MR can be protected with a resist layer or the like.

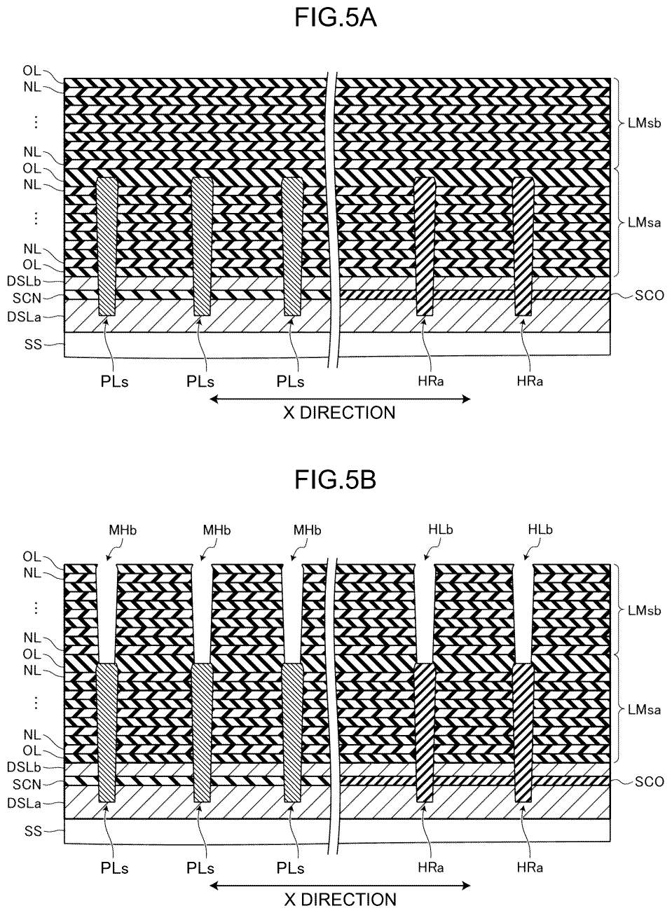

Next, FIGS. 5A to 7B illustrate a state in which the pillars PL and the columnar portions HR are formed. Similarly to FIGS. 4A to 4C described above, FIGS. 5A to 7B illustrate cross sections along the X direction of the semiconductor memory device 1 in the middle of manufacturing.

As illustrated in FIG. 5A, a silicon oxide layer and the like are stacked on the upper surface of the stacked body LMsa. As a result, the uppermost insulating layer OL of the stacked body LMsa becomes thicker than the other insulating layers OL. In addition, the upper end portions of the pillars PLs and the columnar portions HRa are embedded in the uppermost insulating layer OL.

In addition, a stacked body LMsb in which the plurality of insulating layers NL and the plurality of insulating layers OL are alternately stacked one by one is formed on the stacked body LMsa. The stacked body LMsb is a portion in which the insulating layers NL are later replaced with the word lines WL and the select gate lines SGD to become the stacked body LMb.

Note that, at this stage, the plurality of insulating layers OL of the stacked body LMsb including the uppermost insulating layer OL may have substantially the same thickness.

As illustrated in FIG. 5B, a plurality of memory holes MHb penetrating the stacked body LMsb and reaching the upper end portions of the plurality of pillars PLa disposed in the stacked body LMsa is formed in a region that later becomes the memory region MR. In addition, a plurality of holes HLb penetrating the stacked body LMsb and reaching the upper end portions of the plurality of columnar portions HRa disposed in the stacked body LMsa is formed in a region that later becomes the contact region ER.

The memory holes MHb and the holes HLb can be collectively formed, for example. However, the memory holes MHb and the holes HLb may be individually formed while appropriately protecting the region that later becomes the memory region MR and the region that later becomes the contact region ER.

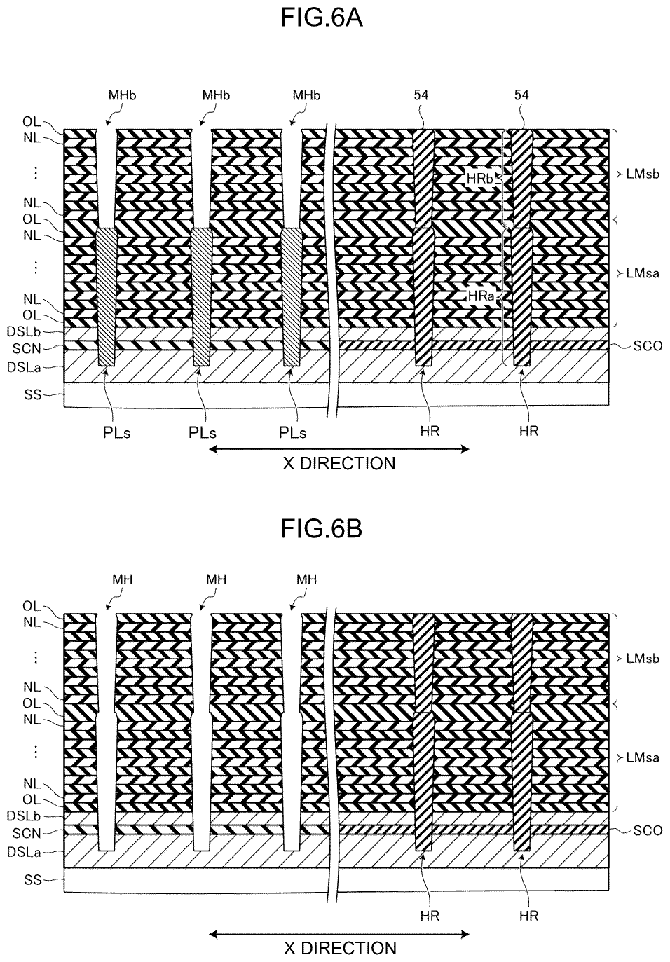

As illustrated in FIG. 6A, in the region that later becomes the contact region ER, the holes HLb are filled with the insulating layers 54 such as silicon oxide layers, for example, to form the plurality of columnar portions HRb. As a result, the columnar portions HR including the columnar portions HRa and HRb are formed.

Note that, when the columnar portions HRb are formed, the region that later becomes the memory region MR can be protected with a resist layer or the like.

As illustrated in FIG. 6B, in the region that later becomes the memory region MR, the sacrificial layers are removed from the plurality of pillars PLa connected to the lower end portions of the plurality of memory holes MHb via the plurality of memory holes MHb. As a result, a plurality of memory holes MH penetrating the stacked bodies LMsa and LMsb and reaching the source line SL is formed.

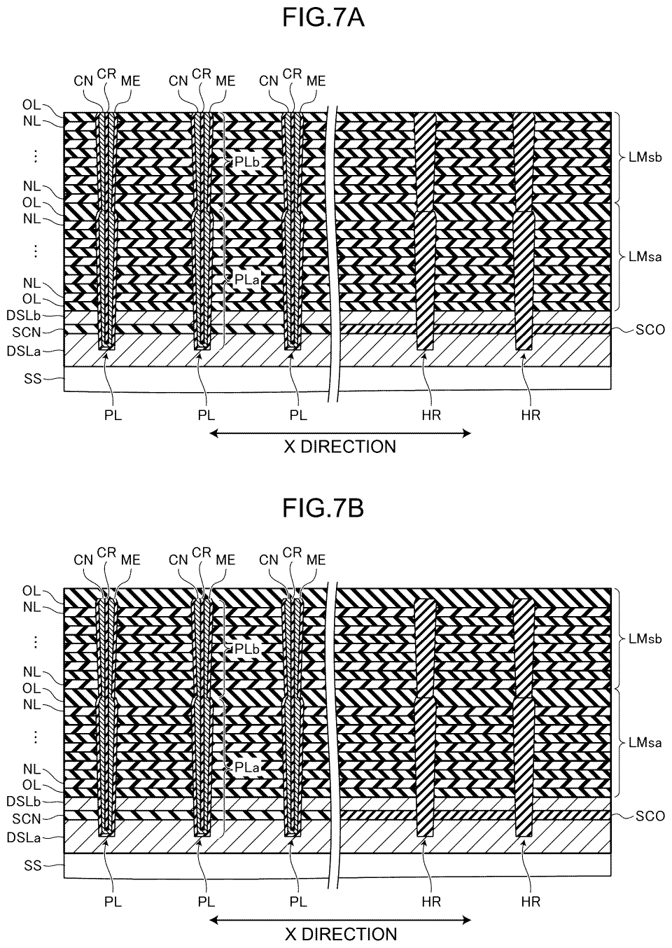

As illustrated in FIG. 7A, the memory layer ME having a stacked structure of the block insulating layer BK, the charge storage layer CT, and the tunnel insulating layer TN (see FIGS. 2B and 2C) is formed in each of the plurality of memory holes MH in order from the outer peripheral side of the memory hole MH. In addition, the channel layers CN are formed on the side walls and the bottom surfaces of the plurality of memory holes MH via the memory layers ME. In addition, a gap in the memory hole MH inside the channel layer CN is filled with a silicon oxide layer or the like to form the core layer CR.

At this time, the memory layer ME, the channel layer CN, and the core layer CR are also formed on the upper surface of the stacked body LMsb. The memory layer ME, the channel layer CN, and the core layer CR are removed from the upper surface of the stacked body LMsb by etch-back or the like.

As described above, the plurality of pillars PL is formed in the region that later becomes the memory region MR. However, at this time point, the memory layers ME cover the entire side walls of the plurality of pillars PL, and the channel layers CN are not in an exposed state.

Note that, in the region that later becomes the contact region ER, the plurality of columnar portions HR has been formed by the above-described treatment of FIG. 6A. Accordingly, the region that later becomes the contact region ER is not affected by the treatment illustrated in FIGS. 6B and 7A described above.

As illustrated in FIG. 7B, a silicon oxide layer and the like are stacked on the upper surface of the stacked body LMsb. As a result, the uppermost insulating layer OL of the stacked body LMsb becomes thicker than the other insulating layers OL. In addition, the upper end portions of the pillars PL and the columnar portions HR are embedded in the uppermost insulating layer OL.

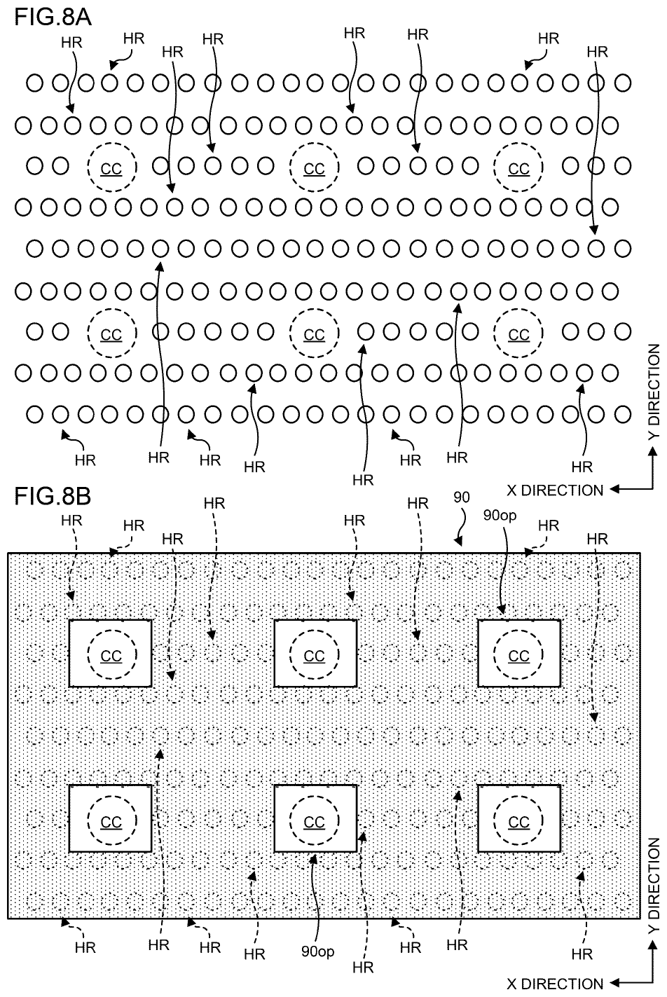

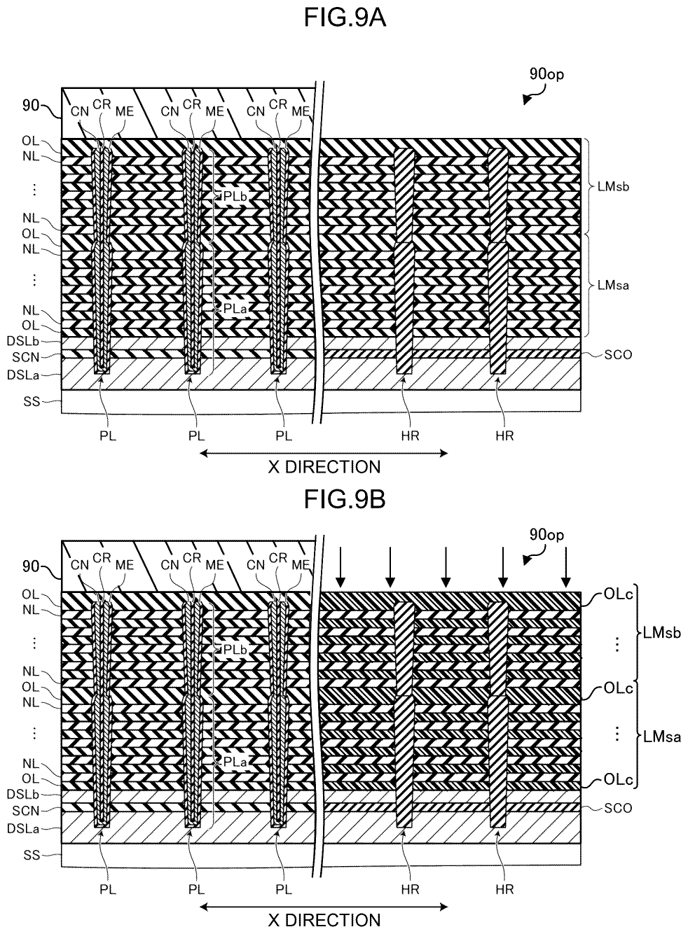

Next, FIGS. 8A to 9B illustrate a state in which the plurality of insulating layers OLc is formed in the region that later becomes the contact region ER.

FIGS. 8A and 8B are top views of a region that later becomes the contact region ER. However, for convenience of description, the plurality of columnar portions HR is illustrated in FIG. 8.

As illustrated in FIG. 8A, in the region that later becomes the contact region ER, the plurality of columnar portions HR has been formed. In addition, regions where the contacts CC are formed later are indicated by broken lines. In this manner, the contacts CC are formed in regions surrounded by the plurality of columnar portions HR when viewed from the stacking direction of the stacked bodies LMsa and LMsb.

As illustrated in FIG. 8B, a resist pattern 90 covering the upper surface of the stacked body LMsb is formed. The resist pattern 90 has openings 90op in regions where the contacts CC are formed later.

Similarly to FIGS. 4A to 7B described above, FIGS. 9A and 9B are cross-sectional views along the X direction of the semiconductor memory device 1 in the middle of manufacturing, including a region that later becomes the memory region MR and a region that later becomes the contact region ER, and illustrate a state after the resist pattern 90 is formed.

As illustrated in FIG. 9A, and as described above with reference to FIGS. 8A and 8B, the resist pattern 90 having the openings 90op is formed in the region that later becomes the contact region ER and the region where the contacts CC are to be formed.

As illustrated in FIG. 9B, ion implantation is performed on the openings 90op of the resist pattern 90 using at least one of carbon and nitrogen as a dopant. As a result, the dopant is implanted into the plurality of insulating layers OL in the region overlapping the openings 90op in the stacking direction of the stacked bodies LMsa and LMsb to form the plurality of insulating layers OLc.

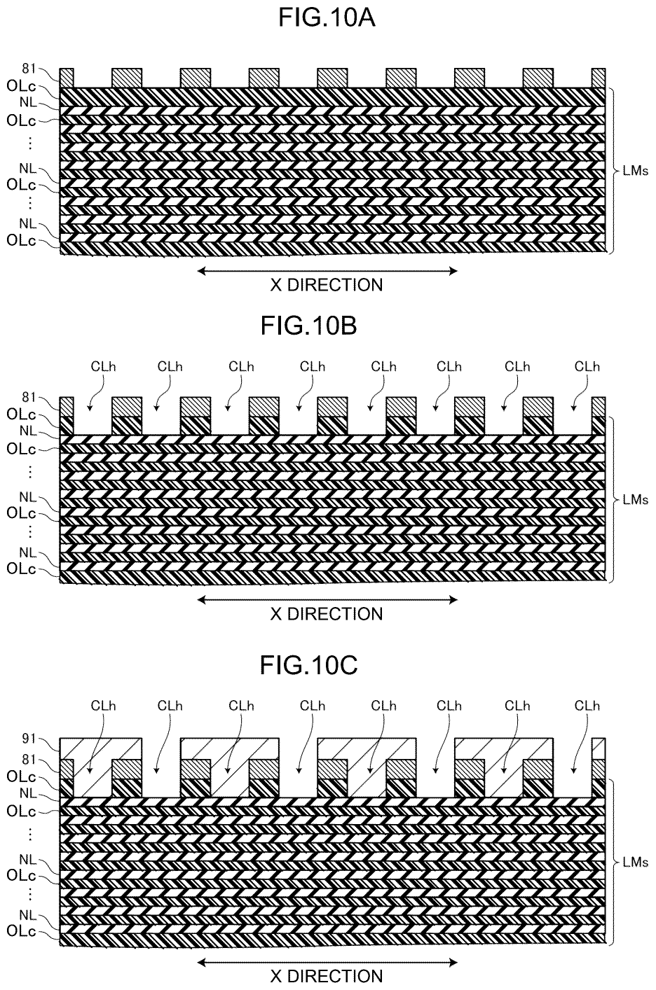

Next, FIGS. 10A to 12C illustrate a state in which a configuration to be the plurality of contacts CC later is formed.

FIGS. 10A to 12C illustrate cross sections along the X direction of the contact region ER in the middle of manufacturing. However, FIGS. 10A to 12C illustrate an example in which contact holes CLa to CLh reaching the respective depth positions of eight insulating layers NL of a stacked body LMs are formed as an example. In addition, in FIGS. 10A to 12C, the plurality of columnar portions HR is not illustrated.

As illustrated in FIG. 10A, a hard mask pattern 81 having a plurality of openings is formed on the upper surface of the stacked body LMs. The hard mask pattern 81 is an inorganic layer that is not removed by ashing using, for example, oxygen plasma. Each of the plurality of openings of the hard mask pattern 81 has, for example, a hole shape.

As illustrated in FIG. 10B, the upper surface of the stacked body LMs exposed from the openings of the hard mask pattern 81 is etched to remove the uppermost insulating layer OLc. As a result, a plurality of contact holes CLh penetrating the uppermost insulating layer OLc and reaching the insulating layer NL immediately below the insulating layer OLc is formed.

As illustrated in FIG. 10C, a resist pattern 91 partially covering the upper surface of the stacked body LMs via the hard mask pattern 81 and having a plurality of openings is formed. The resist pattern 91 is an organic layer such as a resist layer that can be removed by ashing using, for example, oxygen plasma. For example, every other contact hole CLh is exposed from the opening of the resist pattern 91.

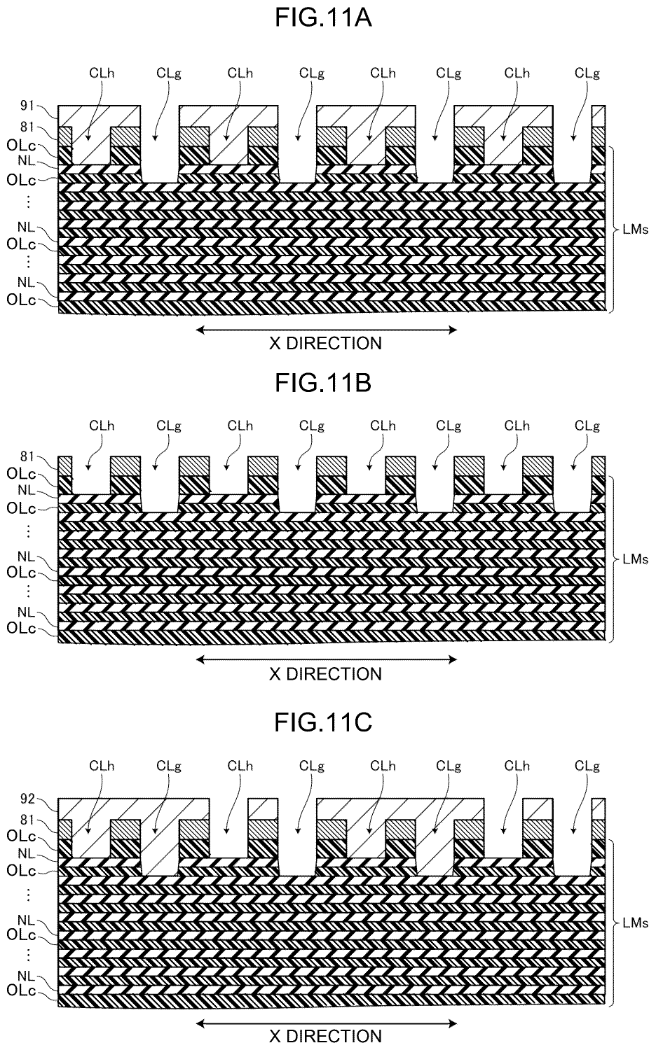

As illustrated in FIG. 11A, the contact hole CLh exposed from the opening of the resist pattern 91 is further etched to remove, for example, a pair of insulating layers NL and OLc from the bottom surface of the contact hole CLh.

As a result, a plurality of contact holes CLg penetrating the stacked body LMs to the second insulating layer OLc from the uppermost insulating layer OLc and reaching the second insulating layer NL from the uppermost insulating layer NL is formed. These contact holes CLg are disposed every other of the contact hole CLh of the plurality of contact holes CLh covered with the resist pattern 91.

That is, at this stage, the plurality of contact holes CLh and the plurality of contact holes CLg are alternately formed one by one in the stacked body LMs.

As illustrated in FIG. 11B, the resist pattern 91 is removed by ashing using oxygen plasma or the like.

As illustrated in FIG. 11C, a resist pattern 92 partially covering the upper surface of the stacked body LMs via the hard mask pattern 81 and having a plurality of openings is formed. The contact holes CLh and CLg are exposed from the openings of the resist pattern 92, for example, every other set among the sets of contact holes CLh and CLg adjacent to each other.

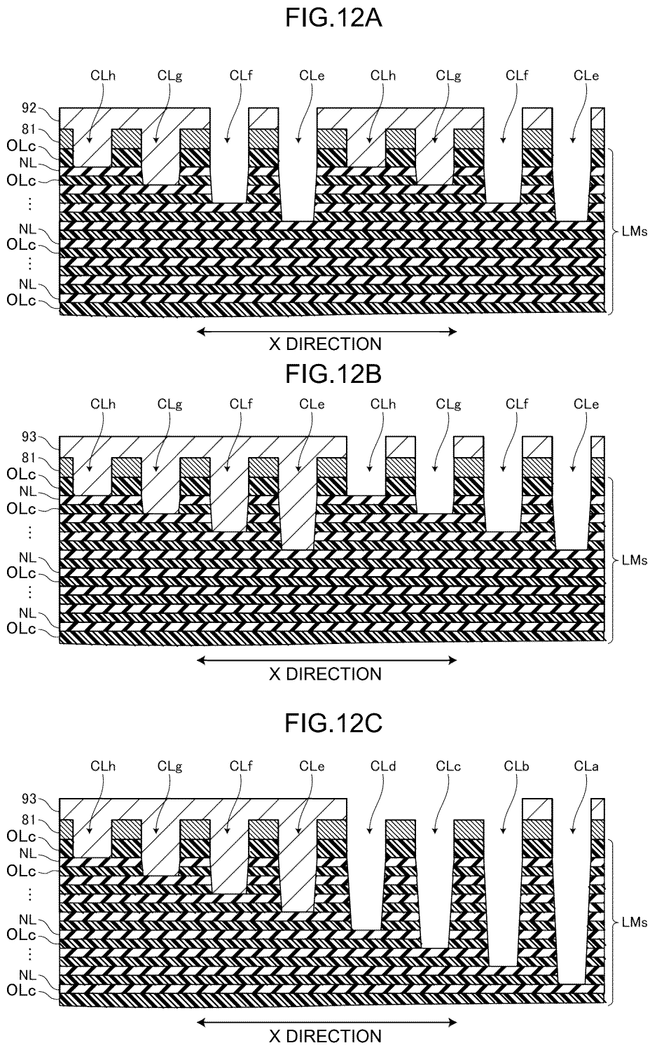

As illustrated in FIG. 12A, the contact holes CLh and CLg exposed from the openings of the resist pattern 92 are further etched to remove, for example, two pairs of insulating layers NL and OLc from the bottom surfaces of the contact holes CLh and CLg.

As a result, from the contact holes CLh to be etched, a plurality of contact holes CLf penetrating the stacked body LMs to the third insulating layer OLc from the uppermost insulating layer OLc and reaching the third insulating layer NL from the uppermost insulating layer NL is formed.

In addition, from the contact holes CLg to be etched, a plurality of contact holes CLe penetrating the stacked body LMs to the fourth insulating layer OLc from the uppermost insulating layer OLc and reaching the fourth insulating layer NL from the uppermost insulating layer NL is formed.

As described above, by the treatment so far, two sets of the contact holes CLh to CLe in which the contact holes CLh to CLe whose reach depths in the stacked body LMs sequentially increase are arranged in this order are formed.

Thereafter, the resist pattern 92 is removed by ashing using oxygen plasma or the like.

As illustrated in FIG. 12B, a resist pattern 93 partially covering the upper surface of the stacked body LMs via the hard mask pattern 81 and having a plurality of openings is formed. One set of contact holes CLh to CLe is exposed from the openings of the resist pattern 93 among the two sets of contact holes CLh to CLe.

As illustrated in FIG. 12C, the contact holes CLh to CLe exposed from the openings of the resist pattern 92 are further etched to remove, for example, four pairs of insulating layers NL and OLc from the bottom surfaces of the contact holes CLh to CLe.

As a result, from the contact holes CLh to be etched, a contact hole CLd penetrating the stacked body LMs to the fifth insulating layer OLc from the uppermost insulating layer OLc and reaching the fifth insulating layer NL from the uppermost insulating layer NL is formed.

In addition, from the contact holes CLg to be etched, a contact hole CLc penetrating the stacked body LMs to the sixth insulating layer OLc from the uppermost insulating layer OLc and reaching the sixth insulating layer NL from the uppermost insulating layer NL is formed.

In addition, from the contact holes CLf to be etched, a contact hole CLb penetrating the stacked body LMs to the seventh insulating layer OLc from the uppermost insulating layer OLc and reaching the seventh insulating layer NL from the uppermost insulating layer NL is formed.

In addition, from the contact holes CLe to be etched, a contact hole CLa penetrating the stacked body LMs to the eighth insulating layer OLc from the uppermost insulating layer OLc and reaching the eighth insulating layer NL from the uppermost insulating layer NL is formed.

As described above, the reach depth in the stacked body LMs sequentially increases, and the plurality of contact holes CLh to CLa reaching the respective eight insulating layers NL in the stacked body LMs is formed. Thereafter, the resist pattern 93 is removed by ashing using oxygen plasma or the like. In addition, the hard mask pattern 81 is removed by etching or the like.

However, various methods are conceivable for forming the contact holes CL to be the contacts CC of the first embodiment, and the methods illustrated in FIGS. 10A to 12C described above are merely examples thereof.

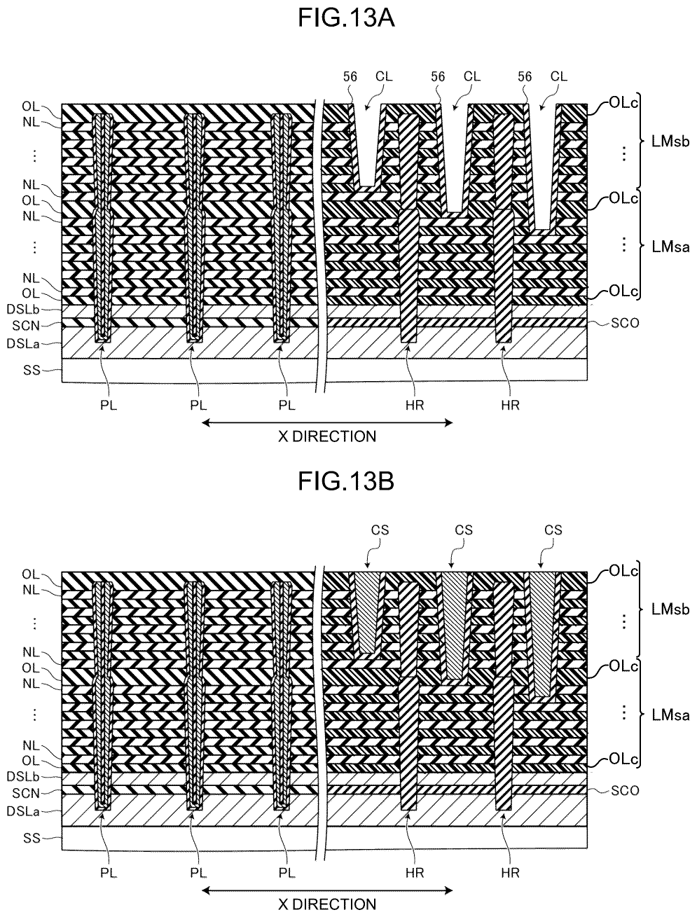

Similarly to FIGS. 9A and 9B described above, FIGS. 13A and 13B illustrate cross sections along the X direction of the semiconductor memory device 1 in the middle of manufacturing. By the treatment of FIGS. 10A to 12C described above, a plurality of contact holes has been formed in the region that later becomes the contact region ER.

FIG. 13A illustrates the contact holes CL reaching the lowermost layer of the stacked body LMsb and the fifth and fourth insulating layers NL from the lowermost layer of the stacked body LMsa among the plurality of contact holes reaching different insulating layers NL in the stacked bodies LMsa and LMsb.

As illustrated in FIG. 13A, the insulating layers 56 that cover the side walls and the bottom surfaces of the plurality of contact holes CL are formed. The insulating layer 56 is, for example, a silicon oxide layer or the like.

As illustrated in FIG. 13B, each of the plurality of contact holes CL is filled with a sacrificial layer such as an amorphous silicon layer via the insulating layer 56. As a result, a plurality of columnar bodies CS is formed. These columnar bodies CS are contact-like temporary structural bodies configured to include sacrificial layers.

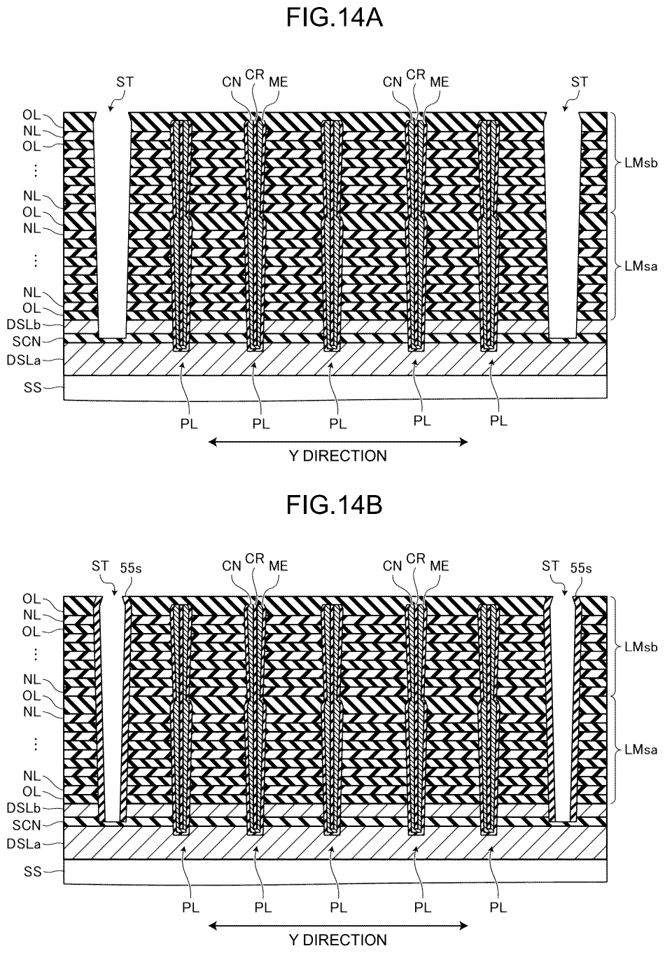

Next, a state in which the source line SL and the word lines WL are formed will be described with reference to FIGS. 14A to 17B. FIGS. 14A to 17B are cross-sectional views along the Y direction of a region that becomes the memory region MR later.

As illustrated in FIG. 14A, slits ST that penetrate the stacked bodies LMsa and LMsb and the upper source line DSLb and reach the intermediate sacrificial layer SCN are formed.

The slits ST also extend in the direction along the X direction in the stacked bodies LMsa and LMsb, that is, in a direction perpendicular to the paper surface. Accordingly, in the region that later becomes the contact region ER, the lower end portions of the slits ST reach the intermediate insulating layer SCO. The slits ST are used for replacement treatment described below, and are configured to be the plate-like contacts LI later.

As illustrated in FIG. 14B, insulating layers 55s are formed on the side walls of the slits ST facing each other in the Y direction. The insulating layers 55s are, for example, silicon oxide layers or the like, and are temporary protective layers formed to protect the stacked bodies LMsa and LMsb in the subsequent treatment, unlike the above-described insulating layers 55 (see FIG. 2A) to be provided on the side walls of the plate-like contacts LI later.

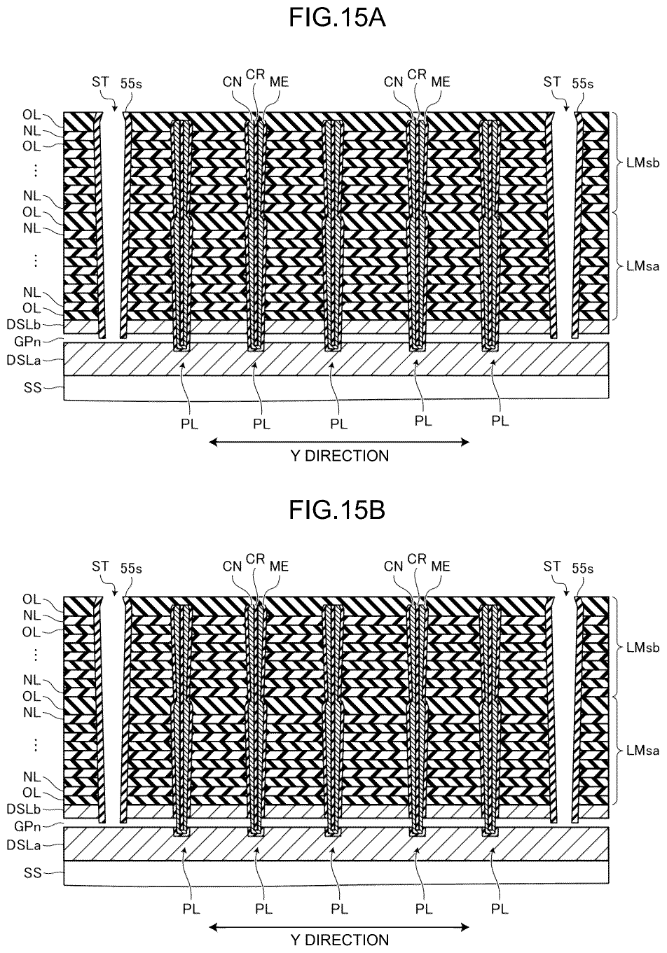

As illustrated in FIG. 15A, a removal liquid of the intermediate sacrificial layer SCN such as hot phosphoric acid is caused to flow through the slits ST whose side walls are protected by the insulating layers 55s, and the intermediate sacrificial layer SCN sandwiched between the lower source line DSLa and the upper source line DSLb is removed.

As a result, a gap layer GPn is formed between the lower source line DSLa and the upper source line DSLb. In addition, a part of the memory layers ME in the outer peripheral portions of the pillars PL is exposed in the gap layer GPn.

At this time, since the side walls of the slits ST are protected by the insulating layers 55s, it is suppressed that the insulating layers NL in the stacked bodies LMsa and LMsb are also removed.

As illustrated in FIG. 15B, a chemical liquid is caused to appropriately flow into the gap layer GPn through the slits ST, and the block insulating layer BK, the charge storage layer CT, and the tunnel insulating layer TN (see FIGS. 2B and 2C) of the memory layer ME exposed in the gap layer GPn are sequentially removed. As a result, the memory layers ME are removed from partial side walls of the pillars PL, and a part of the channel layers CN on the inner side is exposed in the gap layer GPn.

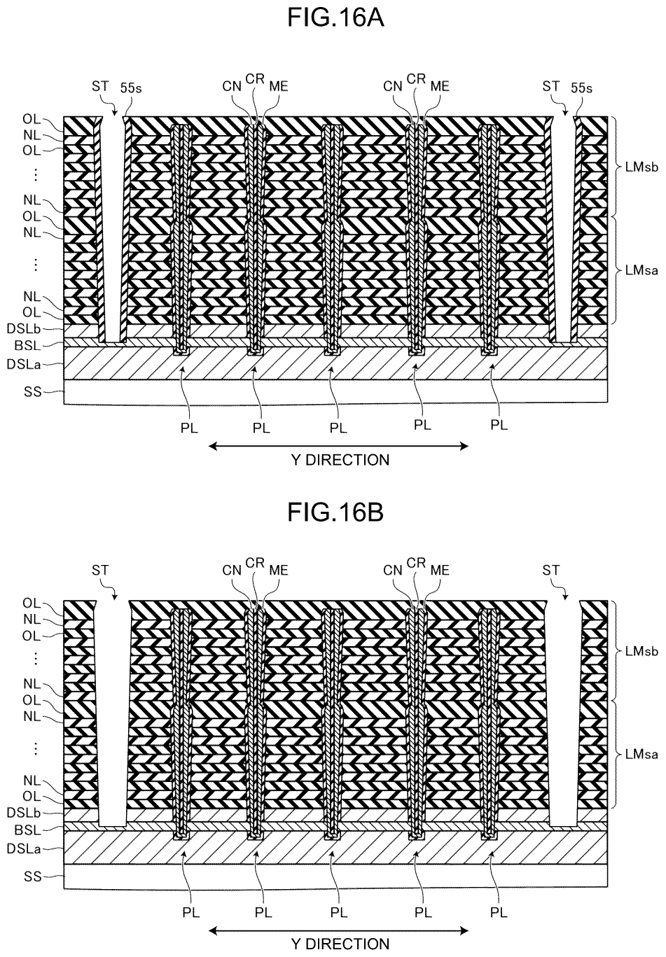

As illustrated in FIG. 16A, a source gas such as amorphous silicon is injected from the slits ST whose side walls are protected by the insulating layers 55s, and the gap layer GPn is filled with amorphous silicon or the like. In addition, the support substrate SS is heat-treated to polycrystallize the amorphous silicon loaded in the gap layer GPn, thereby forming the intermediate source line BSL containing polysilicon or the like.

As a result, a part of the channel layers CN of the pillars PL is connected to the source line SL on the side surfaces via the intermediate source line BSL.

As illustrated in FIG. 16B, the insulating layers 55s are removed from the side walls of the slits ST.

Note that, in the region that later becomes the contact region ER, the intermediate insulating layer SCO is formed between the lower source line DSLa and the upper source line DSLb instead of the intermediate sacrificial layer SCN. Therefore, the region that later becomes the contact region ER is not affected by the treatment illustrated in FIGS. 15A to 16B described above.

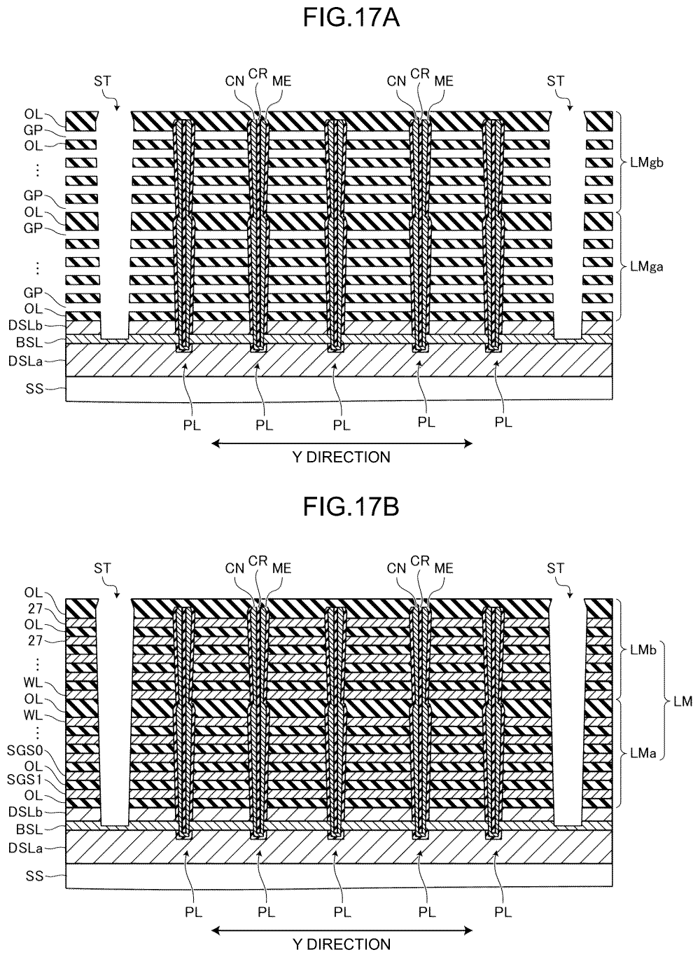

As illustrated in FIG. 17A, a removal liquid of the insulating layers NL such as, for example, hot phosphoric acid is caused to flow into the stacked bodies LMsa and LMsb from the slits ST to remove the insulating layers NL of the stacked bodies LMsa and LMsb. As a result, stacked bodies LMga and LMgb including a plurality of gap layers GP from which the insulating layers NL between the insulating layers OL or the insulating layers OLc are removed are formed.

Note that the stacked bodies LMga and LMgb including the plurality of gap layers GP have a fragile structure. In the region that later becomes the memory region MR, the plurality of pillars PL supports such fragile stacked bodies LMga and LMgb. On the other hand, in the region that later becomes the contact region ER, the plurality of columnar portions HR supports the stacked bodies LMga and LMgb.

Such a support structure of the pillars PL and the columnar portions HR suppresses bending of the remaining insulating layers OL and OLc and distortion or collapse of the stacked bodies LMga and LMgb.

As illustrated in FIG. 17B, a source gas of a conductive material such as tungsten or molybdenum is injected from the slits ST into the stacked bodies LMga and LMgb, and the gap layers GP of the stacked bodies LMga and LMgb are filled with the conductive material to form the plurality of word lines WL and the like.

As a result, the stacked body LM including stacked bodies LMa and LMb in which the plurality of word lines WL and the like and the plurality of insulating layers OL and OLc are alternately stacked one by one is formed. However, the separation layers SHE are not formed at this time point, and one or more conductive layers 27 including the uppermost conductive layer 27 of the stacked body LMb are not the select gate lines SGD separated into a plurality of sections.

As described above, the treatment of forming the intermediate source line BSL from the intermediate sacrificial layer SCN and the treatment of forming the word lines WL from the insulating layers NL are also referred to as replacement treatment.

Thereafter, the insulating layers 55 are formed on the side walls of the slits ST, and the insulating layers 55 are filled with the conductive layers 25 to form the plate-like contacts LI to be the source line contacts. However, the insulating layers 55 or the like may be loaded in the slits ST without forming the conductive layers 25 to form the plate-like members not having the function as a source line contact.

In addition, the plurality of separation layers SHE penetrating one or more conductive layers 27 including the uppermost conductive layer 27 of the stacked body LMb and reaching the insulating layers OL and OLc immediately below is formed. As a result, one or more conductive layers 27 including the uppermost conductive layer 27 of the stacked body LMb are partitioned into a pattern of the select gate lines SGD.

In addition, the sacrificial layers are removed from the plurality of columnar bodies CS to form the plurality of contact holes CL, and the insulating layers 56 covering the bottom surfaces of the plurality of contact holes CL are removed. In addition, the conductive layer 26 such as a tungsten layer is loaded into each of the plurality of contact holes CL whose side walls are covered by the insulating layers 56. Thus, the plurality of contacts CC is formed.

In addition, the insulating layer 52 is formed on the upper surface of the stacked body LMb, and plugs CH and V0 penetrating the insulating layer 52 are formed. The plugs CH and V0 are connected to the upper end portions of the pillars PL and the contacts CC, respectively. In addition, the insulating layer 53 is formed on the insulating layer 52, and the bit line BL and the upper wiring MX are formed in the insulating layer 53. The bit line BL is connected to the pillars PL via the plugs CH, and the upper wiring MX is connected to the contacts CC via the plugs V0.

Note that, for example, the plugs CH and the bit line BL, the plugs V0 and the upper wiring MX, and the like may be collectively formed by using a dual damascene method or the like.

In addition, the electrode pad PDb connected to the bit line BL and the upper wiring MX is formed.

On the other hand, the peripheral circuits CBA are formed on the semiconductor substrate SB separate from the support substrate SS on which the stacked body LM is formed, and are covered with the insulating layer 40. In the insulating layer 40, contacts, vias, wiring, or the like that lead the peripheral circuits CBA to the surface of the insulating layer 40 are formed and connected to the electrode pad PDc or the like formed on the surface of the insulating layer 40.

In addition, the support substrate SS and the semiconductor substrate SB are bonded to each other by the insulating layers 50 and 40, and the electrode pads PDb and PDc in the insulating layers 50 and 40 are connected. Thereafter, the support substrate SS is ground and removed to expose the source line SL, and the electrode film EL is connected via the insulating layer 60 in which the plugs PG are formed.

Thus, the semiconductor memory device 1 of the first embodiment is manufactured.

### (Overview)

The semiconductor memory device such as a three-dimensional nonvolatile memory is manufactured including a process of replacing the plurality of sacrificial layers with the plurality of word lines, for example. In such replacement treatment, the insulating layer remaining in the stacked body from which the sacrificial layer has been removed may be bent. When the bending of the insulating layer occurs, for example, the gap layer GP in which the word line is formed may be blocked.

At this time, in the region that later becomes the memory region, the plurality of pillars is periodically disposed at a narrow pitch to support the stacked body at the time of replacement. On the other hand, in the region that later becomes the contact region, the plurality of columnar portions is disposed at a relatively wide pitch and in a state where periodicity is partially lost in order to avoid interference with the contact. Therefore, at the contact disposition position, the pitch of the plurality of columnar portions is further widened, and the blocking of the insulating layer as described above is more likely to occur than in the region that later becomes the memory region.

With the semiconductor memory device 1 of the first embodiment, the insulating layers OLc located in the region including the contacts CC and surrounded by the plurality of columnar portions HR among the plurality of insulating layers OL have, in at least one portion, at least one of a higher Young's modulus, a lower compressive stress, and a higher tensile stress than the insulating layer OL in the disposition region of the pillars PL. As a result, it is possible to suppress the bending of the insulating layers OLc at the time of the replacement treatment.

With the semiconductor memory device 1 of the first embodiment, among the plurality of insulating layers OL and OLc, the insulating layers OLc in the region where the contacts CC are disposed have a higher Young's modulus than the insulating layer OL in the disposition region of the pillars PL over the entire region surrounded by the plurality of columnar portions HR. As a result, it is possible to further suppress the bending of the insulating layers OLc at the time of the replacement treatment.

### First Modification

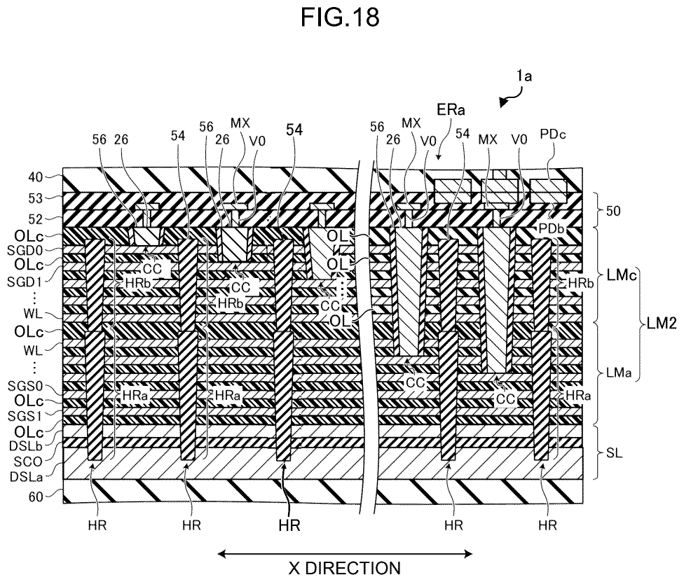

Next, a semiconductor memory device 1a of a first modification of the first embodiment will be described with reference to FIGS. 18 to 20B. The semiconductor memory device 1a of the first modification is different from the semiconductor memory device of the above-described first embodiment in that the insulating layer OLc is provided for each of the stacked bodies LMa and LMc.

In the drawings described below, the same reference numerals are given to the same configurations as those of the first embodiment, and the description thereof may be omitted.

FIG. 18 is a cross-sectional view along an X direction illustrating an example of a configuration of the semiconductor memory device 1a according to the first modification of the first embodiment. As illustrated in

FIG. 18, the semiconductor memory device 1a of the first modification includes a stacked body LM2 including the stacked bodies LMa and LMc.

The stacked body LMa includes the plurality of insulating layers OLc in a contact region ERa as in the above-described first embodiment. In addition, although not illustrated, the stacked body LMa includes the plurality of insulating layers OL in the memory region.

On the other hand, the stacked body LMc includes the plurality of insulating layers OLc further only in a partial region of the contact region ERa. In the other region of the contact region ERa and in the memory region, the stacked body LMb includes the plurality of insulating layers OL. More specifically, the insulating layers OLc of the stacked body LMc are disposed in the region where the contacts CC connected to the word lines WL or the select gate lines SGD included in the stacked body LMb among the plurality of contacts CC are provided in the contact region ERa. That is, in the contact region ERa, the plurality of insulating layers OL is disposed in the region where the contacts CC connected to the word lines WL or the select gate lines SGS included in the stacked body LMa among the plurality of contacts CC are provided, similarly to the memory region.

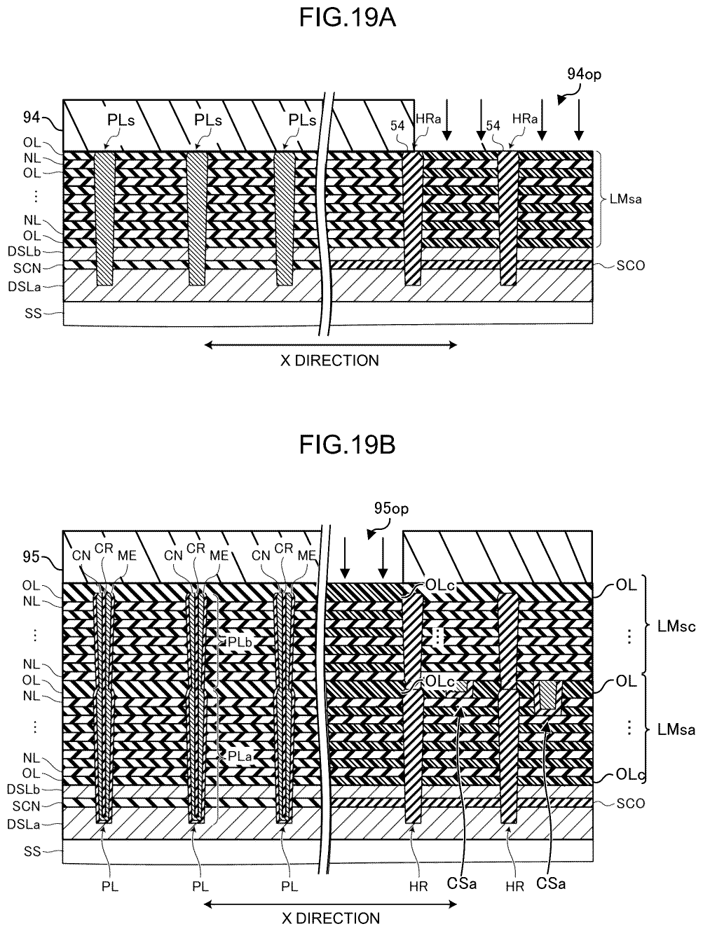

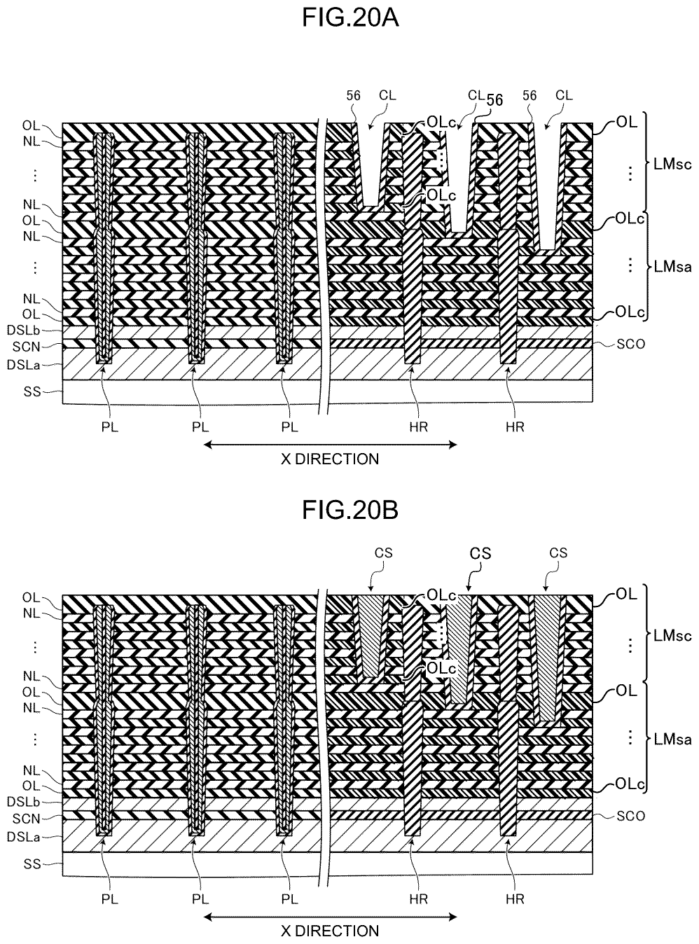

FIGS. 19A to 20B are cross-sectional views sequentially illustrating a part of a procedure of the method for manufacturing the semiconductor memory device 1a according to the first modification of the first embodiment. More specifically, FIGS. 19A to 20B illustrate a cross section along the X direction of the semiconductor memory device 1a in the middle of manufacturing, including a region that later becomes the memory region and a region that later becomes the contact region ERa.

As illustrated in FIG. 19A, in the method for manufacturing the semiconductor memory device 1a of the first modification, for example, after the stacked body LMsa, the pillars PLs, and the columnar portions HRa are formed, ion implantation is performed on a part of the insulating layers OL before the stacked body LMsb is formed.

That is, a resist pattern 94 having openings 94op is formed in a region where the contacts CC connected to the word lines WL or the like in the stacked body LMa are to be formed in the region that later becomes the contact region ERa. In addition, ion implantation is performed on the openings 94op of the resist pattern 94 to form the insulating layers OLc in a partial region of the stacked body LMsa.

As illustrated in FIG. 19B, a plurality of columnar bodies CSa penetrating the insulating layers OLc formed in a partial region of the stacked body LMsa and the insulating layers NL and reaching connection target insulating layers NL is formed. The plurality of columnar bodies CSa has a configuration to become lower structures of the contacts CC connected to the word lines WL or the like in the stacked body LMa later. That is, the plurality of columnar bodies CSa is configured to include sacrificial layers such as amorphous silicon layers similarly to the columnar bodies CS of the first embodiment described above.

In addition, a resist pattern 95 having openings 95op is formed in a region where the contacts CC connected to the word lines WL or the like in the stacked body LMb are to be formed in the region that later becomes the contact region ERa. In addition, ion implantation is performed on the openings 95op of the resist pattern 95 to form the insulating layers OLc in a partial region of the stacked bodies LMsa and LMsb.

As illustrated in FIG. 20A, the plurality of contact holes CL reaching the plurality of insulating layers NL in the stacked bodies LMsa and LMsb is formed in the region that later becomes the contact region ERa.

That is, within the region that later becomes the contact region ERa, in the region where the contacts CC connected to the word lines WL or the like in the stacked body LMb are to be formed, the contact holes CL that penetrate the insulating layers NL and OLc of the stacked body LMsb and reach connection target insulating layers NL are formed.

On the other hand, in the region where the contacts CC connected to the word lines WL or the like in the stacked body LMa are to be formed, the plurality of contact holes penetrating the insulating layers NL and OL of the stacked body LMsb and connected to the already formed columnar bodies CSa is formed, and the sacrificial layers are temporarily removed from the columnar bodies CSa through these contact holes. As a result, the contact holes CL that penetrate the insulating layers NL and OL of the stacked bodies LMsb and LMsa and reach the connection target insulating layers NL are formed.

Thereafter, the insulating layers 56 covering the side walls and the bottom surfaces of the contact holes CL are formed again.

As illustrated in FIG. 20B, sacrificial layers such as amorphous silicon layers are again loaded into the contact holes CL in which the insulating layers 56 are formed. As a result, the plurality of columnar bodies CS is formed in the region that later becomes the contact region ERa.

The subsequent processes are performed in the same manner as in the first embodiment described above.

As described above, since the plurality of columnar portions HR is disposed while avoiding interference with the contacts CC, the interval between the columnar portions HR becomes wide around the contacts CC, and the bending of the insulating layer OL at the time of replacement easily occurs. Here, the risk of bending of the insulating layer OL is higher in the region below the columnar bodies CS than in the portions of the stacked bodies LMsa and LMsb through which the columnar bodies CS to be the contacts CC later penetrate. This is because neither the columnar bodies CS nor the columnar portions HR are disposed in the region below the columnar bodies CS.

With the semiconductor memory device 1a of the first modification, the insulating layers OLc in the stacked body LMa in the region where the contacts CC connected to the word lines WL or the like in the stacked body LMa are disposed have, over the entire region surrounded by the plurality of columnar portions HR, at least one of a higher Young's modulus, a lower compressive stress, and a higher tensile stress than the insulating layer OL in the stacked body LMb in the region where the contacts CC connected to the word lines WL or the like in the stacked body LMb are disposed and the insulating layer OL in the disposition region of the pillars PL.

As described above, the effect of suppressing the bending of the insulating layer OLc can also be sufficiently obtained by providing the insulating layer OLc by performing ion implantation only on the region below the contacts CC where the risk of bending of the insulating layer OL is further increased. On the other hand, when a hard insulating layer OLc is not formed in the portion where the columnar bodies CS penetrate the stacked body LMb in which the risk of bending of the insulating layer OL is relatively low, for example, it is easy to form contacts CC connected to the word lines WL or the like of the stacked body LMa and having a high aspect ratio can be easily formed.

With the semiconductor memory device 1a of the first modification, the same effects as those of the semiconductor memory device 1 of the first embodiment described above are obtained.

Note that, in the first embodiment described above, after the stacked bodies LMsa and LMsb are formed, the contact holes CL to be the contacts CC connected to the word lines WL or the like in the stacked body LMa or in the stacked body LMb are collectively formed. However, also in the configuration of the first embodiment described above in which the insulating layers OLc are formed in both the stacked bodies LMa and LMb in the contact region ER, the contact holes may be formed for each of the stacked bodies LMa and LMb.

As a result, it is easy to form the contact holes penetrating the stacked bodies LMsa and LMsb in which a hard insulating layer OLc is formed.

### Second Modification

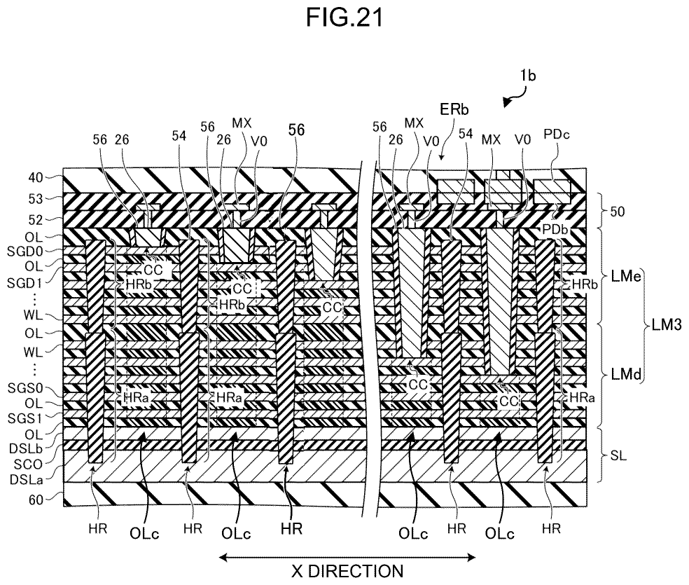

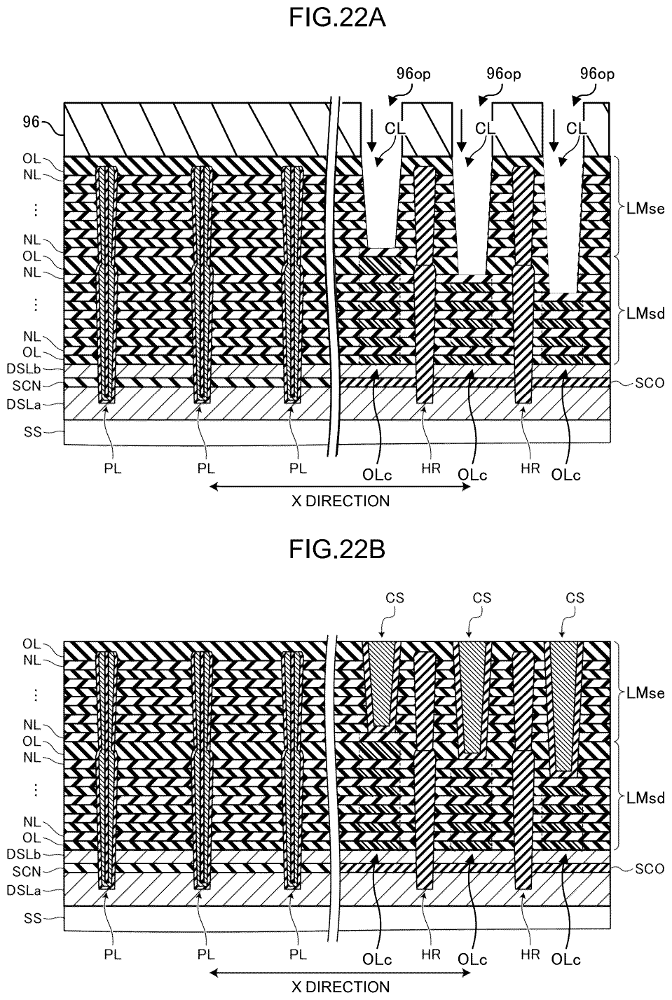

Next, a semiconductor memory device 1b of a second modification of the first embodiment will be described with reference to FIGS. 21 to 22B. The semiconductor memory device 1b of the second modification is different from the semiconductor memory device of the first embodiment described above in that the insulating layer OLc is provided in a portion overlapping the contact CC in the stacking direction.

In the drawings described below, the same reference numerals are given to the same configurations as those of the first embodiment, and the description thereof may be omitted.

FIG. 21 is a cross-sectional view along an X direction illustrating an example of a configuration of the semiconductor memory device 1b according to the second modification of the first embodiment. As illustrated in FIG. 21, the semiconductor memory device 1b of the second modification includes a stacked body LM3 including stacked bodies LMd and LMe.

In the stacked bodies LMd and LMe, insulating layers OLc are provided below the individual contacts CC in a contact region ERb and in portions overlapping these contacts CC in the stacking direction.

That is, for example, in the contact CC portion connected to the uppermost select gate line SGD0 of the stacked body LMb, the stacked body LMa and LMb portion overlapping the contact CC in the stacking direction and below the select gate line SGD0 is entirely the insulating layer OLc. In addition, for example, in the contact CC portion connected to the uppermost word line WL of the stacked body LMa, the insulating layer OLc is not provided in the stacked body LMb above the contact CC, and the stacked body LMa portion overlapping the contact CC in the stacking direction and below the uppermost word line WL of the stacked body LMa is entirely the insulating layer OLc.

FIGS. 22A and 22B are cross-sectional views illustrating a part of a procedure of a method for manufacturing the semiconductor memory device 1b according to the second modification of the first embodiment. More specifically, FIGS. 22A and 22B illustrate a cross section along the X direction of the semiconductor memory device 1b in the middle of manufacturing, including a region that later becomes the memory region and a region that later becomes the contact region ERb.

As illustrated in FIG. 22A, in the method for manufacturing the semiconductor memory device 1b of the second modification, for example, before the insulating layers OLc are formed, the plurality of contact holes CL is formed using a resist pattern 96 having a plurality of openings 96op as a mask. In addition, ion implantation is performed from the bottom surfaces of the contact holes CL exposed from the openings 96op of the resist pattern 96 to form the insulating layers OLc below the contact holes CL and at portions overlapping the contact holes CL in the stacking direction.

As illustrated in FIG. 22B, the insulating layers 56 and the sacrificial layers are formed in the contact holes CL to form the plurality of columnar bodies CS.

The subsequent processes are performed in the same manner as in the first embodiment described above.

With the semiconductor memory device 1b of the second modification, the insulating layer OLc in the region where the contact CC is disposed has, in the portion overlapping the contact CC in the stacking direction, at least one of a higher Young's modulus, a lower compressive stress, and a higher tensile stress than the insulating layer OL in the disposition region of the pillar PL.

As described above, by disposing the insulating layer OLc only at a position overlapping the contact CC in the stacking direction, the effect of suppressing the bending of the insulating layer OLc can be sufficiently obtained.

In addition, with the configuration in which the insulating layer OLc is disposed as described above, the formation of the contact holes CL and the ion implantation can be performed using, for example, the same one resist pattern 96, and the number of processes can be reduced and the manufacturing cost can be reduced. In addition, since the hard insulating layer OLc is formed after the formation of the contact hole CL, the formation of the contact hole CL is further facilitated.

With the semiconductor memory device 1b of the second modification, the same effects as those of the semiconductor memory device 1 of the first embodiment described above are obtained.

### Second Embodiment

Hereinafter, a second embodiment will be described in detail with reference to the drawings. A semiconductor memory device of the second embodiment is different from the semiconductor memory device of the first embodiment described above in that, for example, an insulating layer having a high Young's modulus is disposed around a columnar portion supporting a stacked body.

In the drawings described below, the same reference numerals are given to the same configurations as those of the first embodiment, and the description thereof may be omitted.

### Configuration Example of Semiconductor Memory Device

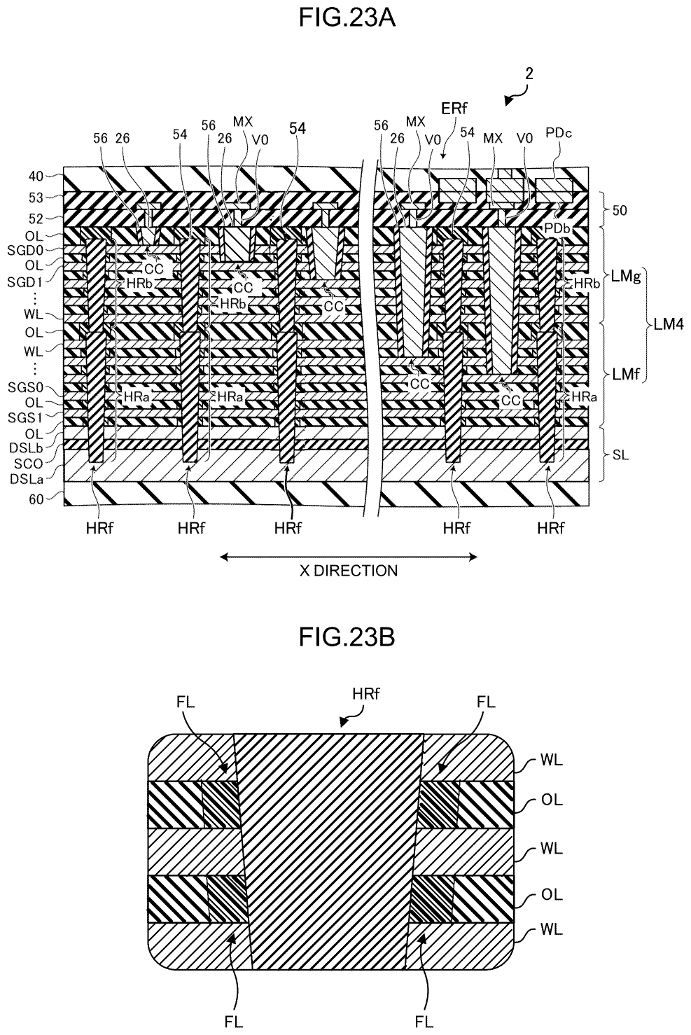

FIGS. 23A and 23B are cross-sectional views along an X direction illustrating an example of a configuration of a semiconductor memory device 2 according to the second embodiment. More specifically, FIG. 23A is a cross-sectional view along an X direction illustrating an example of a configuration of a contact region ERf of the second embodiment. FIG. 23B is an enlarged cross-sectional view of a columnar portion HRf of the second embodiment.

As illustrated in FIGS. 23A and 23B, the semiconductor memory device 2 of the second embodiment includes a stacked body LM3 including stacked bodies LMf and LMg. Each of the stacked bodies LMf and LMg has a configuration in which a plurality of word lines and the like and insulating layers OL are alternately stacked one by one.

In addition, the columnar portion HRf of the second embodiment has a plurality of flange portions FL on the side wall at the height positions of the plurality of insulating layers OL of a stacked body LM4. The plurality of flange portions FL is provided so as to surround the outer edge portions of the individual columnar portions HRf, and protrudes from the side wall portions of the columnar portions HRf toward the plurality of insulating layers OL side. The plurality of flange portions FL is, for example, a silicon oxide layer containing at least one of carbon and nitrogen, and has at least one of a higher Young's modulus, a lower compressive stress, and a higher tensile stress than the insulating layer OL of the stacked body LM4.

The outer edge portion of each of the plurality of flange portions FL is located at a position substantially equidistant from the center point of each of the plurality of columnar portions HRf viewed from the stacking direction. That is, the outer edge portion of each of the plurality of flange portions FL is provided substantially concentrically with the side wall portion of each of the plurality of columnar portions HR at the height positions of the plurality of word lines WL and the like.

In other words, in the semiconductor memory device 2 of the second embodiment, it can be considered that the insulating layer OLc is provided around the columnar portion HR of the first embodiment described above so as to be in contact with the side wall of the columnar portion HR. At this time, the columnar portion HR can also be regarded as corresponding to the core material of the columnar portion HRf having the flange portions FL.

### (Method for Manufacturing Semiconductor Memory Device)

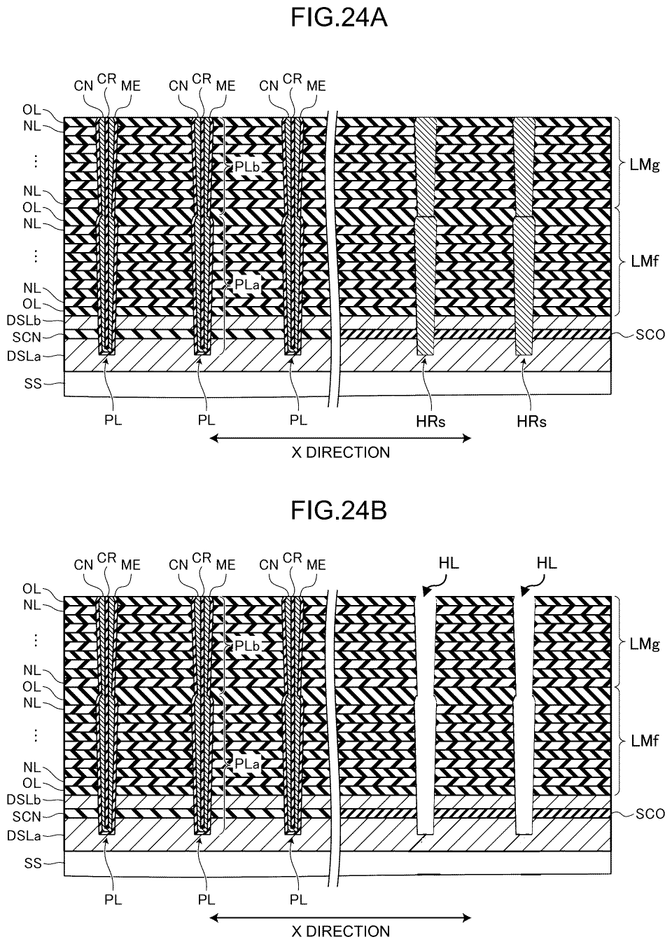

Next, a method for manufacturing the semiconductor memory device 2 of the second embodiment will be described with reference to FIGS. 24A to 26B. FIGS. 24A to 26B are views sequentially illustrating a part of a procedure of the method for manufacturing the semiconductor memory device 2 according to the second embodiment.

More specifically, FIGS. 24A to 26B illustrate a cross section along the X direction of the semiconductor memory device 2 in the middle of manufacturing, including a region that later becomes a memory region MR and a region that later becomes the contact region ERf.

As illustrated in FIG. 24A, in the method for manufacturing the semiconductor memory device 2 of the second embodiment, the columnar portions HRa and HRb and the like are not formed for each of the stacked bodies LMsa and LMsb as in the above-described first embodiment, but the columnar portions HRf are collectively formed after a stacked body LMsb is formed.

More specifically, in the method for manufacturing the semiconductor memory device 2 of the second embodiment, for example, after the formation of holes HLa, the holes HLa are filled with sacrificial layers such as amorphous silicon layers instead of the insulating layers 54. In addition, for example, after holes HLb are formed, the holes HLb are filled with sacrificial layers such as amorphous silicon layers instead of the insulating layers 54.

As a result, columnar portions HRs filled with the sacrificial layers are formed in the holes HL penetrating the stacked bodies LMsa and LMsb. By filling the holes HL with the sacrificial layers or the like in this way, for example, it is possible to suppress the holes HL from being processed when pillars PL or the like are formed thereafter.

As illustrated in FIG. 24B, after the pillars PL or the like are formed, the sacrificial layers in the holes HL are removed.

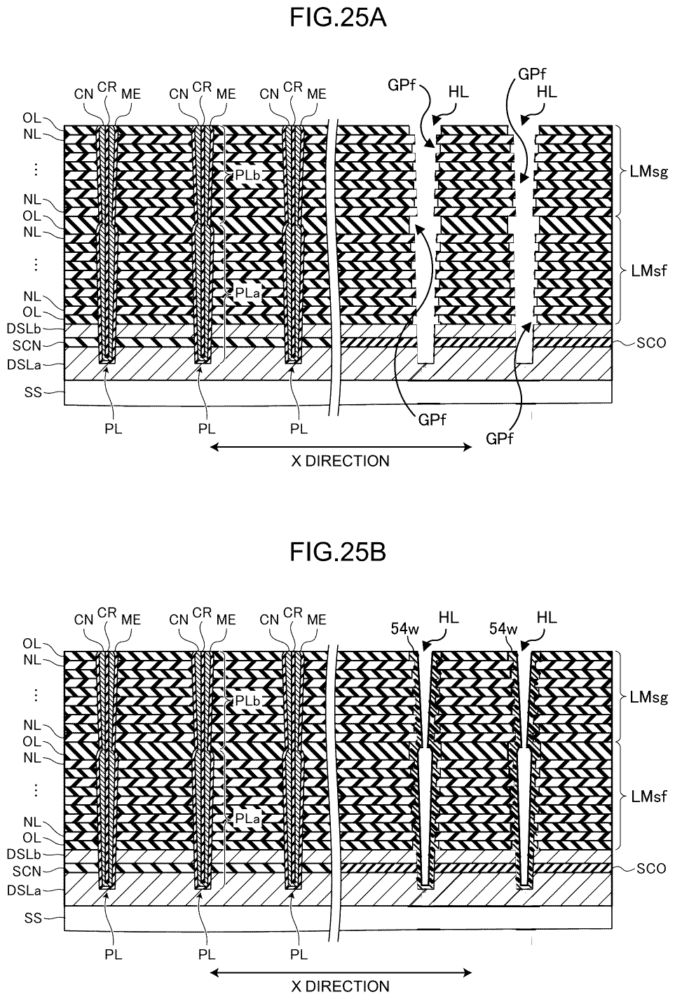

As illustrated in FIG. 25A, a chemical liquid for dissolving the insulating layers OL is injected into the holes HL. As a result, the insulating layers OL exposed on the side walls of the holes HL retreat from the side walls of the holes HL toward the outside of the holes HL. At this time, the retreat amount of the insulating layers OL in the outer peripheral portions of the holes HL is substantially the same in all directions. That is, a plurality of flange-shaped gap layers GPf protruding into the insulating layers OL is thus formed substantially concentrically with respect to the side wall portions of the holes HL remaining at the height position of the insulating layers NL.

Note that the plurality of flange-shaped gap layers GPf may be formed by a method other than the above-described wet etching such as a chemical dry etching method.

As illustrated in FIG. 25B, insulating layers such as silicon oxide layers are formed on the side walls and the bottom surfaces of the holes HL by, for example, atomic layer deposition (ALD) or the like. At this time, for example, at least one of carbon and nitrogen is added to a film-forming gas so that the insulating layer contains carbon or the like at a predetermined concentration.

As a result, insulating layers 54w are formed on the side walls and the bottom surfaces of the holes HL including the plurality of flange-shaped gap layers GPf. However, the insulating layers 54w may be formed by a method other than ALD such as low pressure-chemical vapor deposition (LP-CVD).

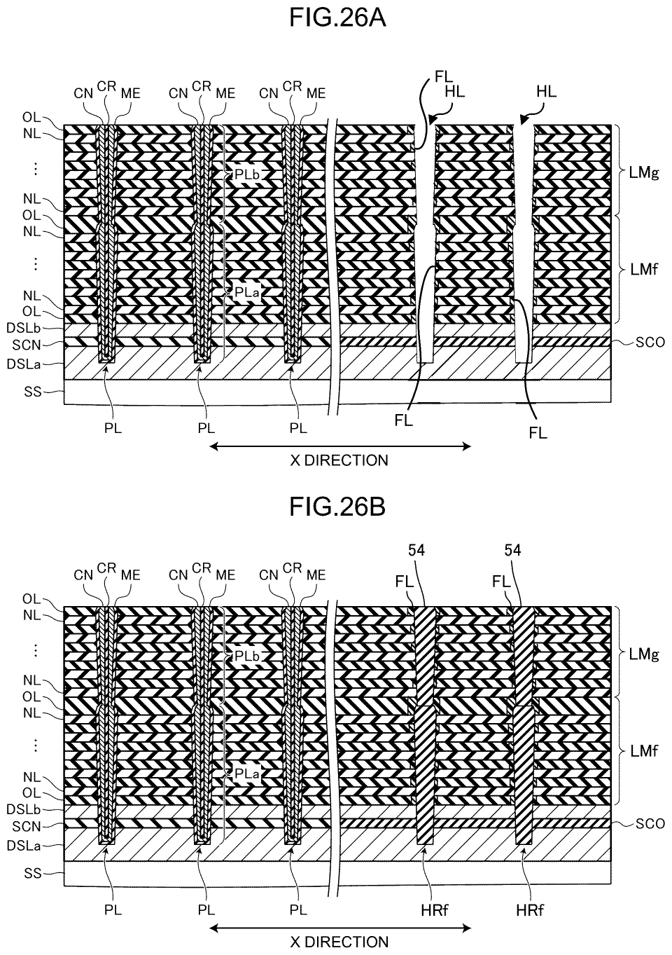

As illustrated in FIG. 26A, the insulating layers 54w formed on the side walls and the bottom surfaces of the holes HL excluding those within the flange-shaped gap layers GPf are removed. As a result, the plurality of flange portions FL in which the insulating layers 54w are loaded in the flange-shaped gap layers GPf is formed.

As illustrated in FIG. 26B, the holes HL are filled with the insulating layers 54. Thus, the columnar portions HRf of the second embodiment are formed.

The subsequent processes are performed in the same manner as in the above-described first embodiment except that ion implantation is not performed on the insulating layers OL of the stacked bodies LMsa and LMsb.

### (Overview)

With the semiconductor memory device 2 of the second embodiment, the plurality of columnar portions HRf includes the plurality of flange portions FL each protruding to the plurality of insulating layers OL at the height positions of the plurality of insulating layers OL and having at least one of a higher Young's modulus, a lower compressive stress, and a higher tensile stress than the plurality of insulating layers OL.

Alternatively, with the semiconductor memory device 2 of the second embodiment, the plurality of insulating layers OLc has at least one of a higher Young's modulus, a lower compressive stress, and a higher tensile stress than the other portions within a predetermined distance from the portion in contact with the plurality of columnar portions HR toward the outside of the plurality of columnar portions HR.

As a result, it is possible to suppress the bending of the insulating layers OL at the time of the replacement treatment.

With the semiconductor memory device 2 of the second embodiment, the same effects as those of the semiconductor memory device 1 of the first embodiment described above are obtained.

Note that, in the second embodiment described above, the insulating layers 54w covering the entire side walls of the holes HL are formed, and then the insulating layers 54w on the side walls are removed to form the flange portions FL. However, the insulating layers 54w may be selectively formed in the flange-shaped gap layers GPf. In this case, for example, a gas preferentially adsorbed to the insulating layers OL can be used as the film-forming gas. Alternatively, inhibitor layers that inhibit the formation of the insulating layers 54w are formed on the insulating layers NL, and then the insulating layers 54w are formed.

As a result, the insulating layers 54w are selectively formed in the flange-shaped gap layers GPf. In addition, as a result, it is possible to obtain a state in which the insulating layers 54w are formed in the flange-shaped gap layers GPf as illustrated in FIG. 26A described above without forming the insulating layers 54 covering the entire side walls of the holes HL as illustrated in FIG. 25B described above.

### First Modification

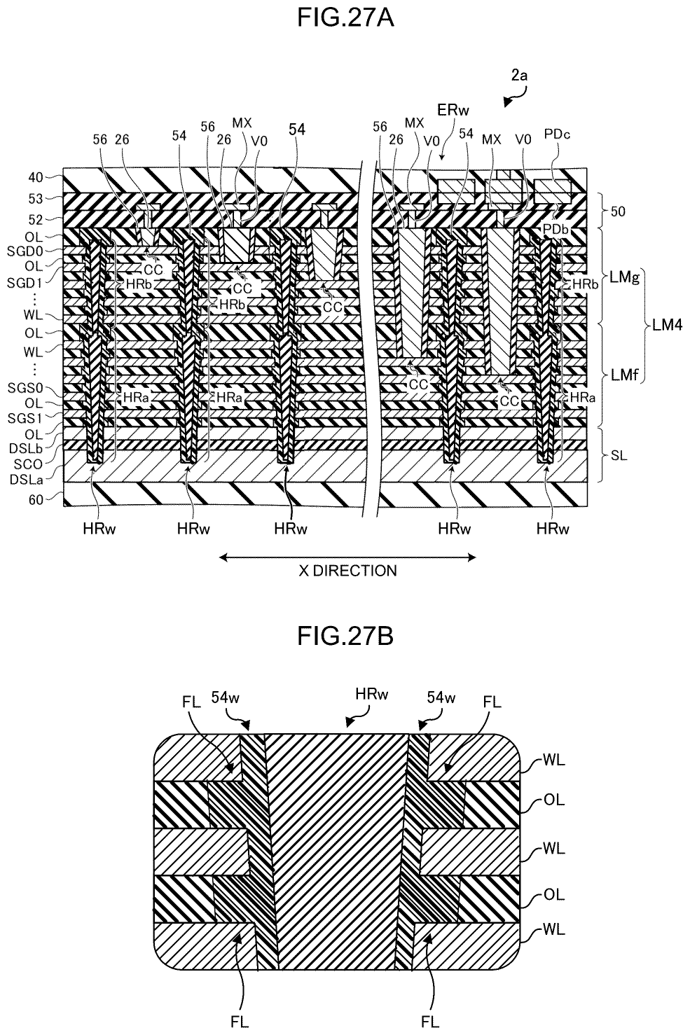

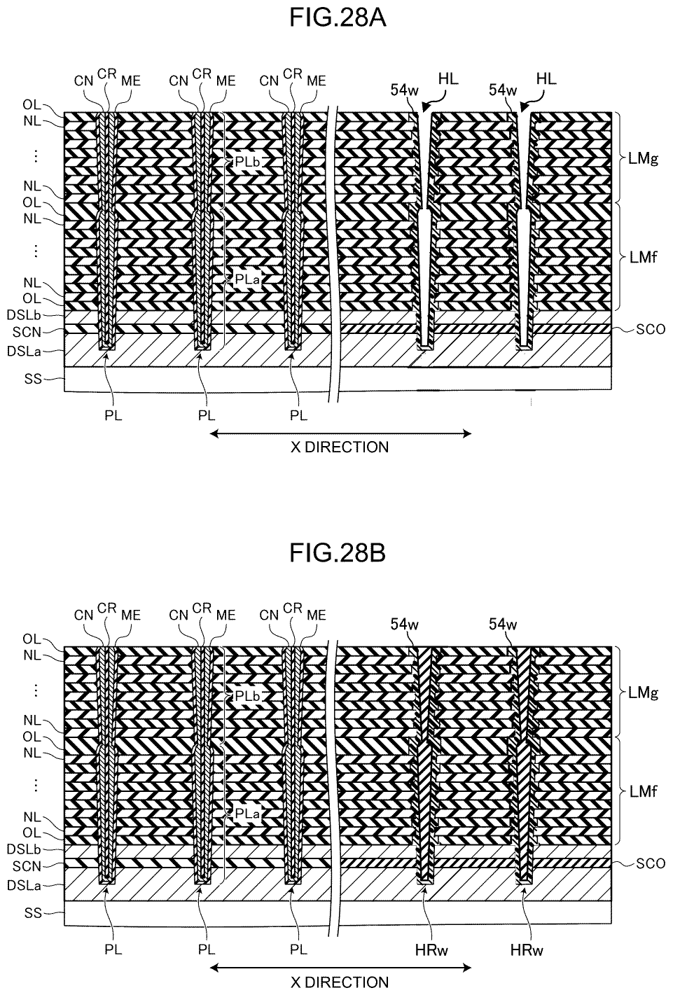

Next, a semiconductor memory device 2a of a first modification of the second embodiment will be described with reference to FIGS. 27A to 28B. The semiconductor memory device 2a of the first modification is different from the semiconductor memory device of the above-described first embodiment in that columnar portions HRw in which the insulating layers 54w are provided on the side walls are provided in addition to the flange portions FL.

In the drawings described below, the same reference numerals are given to the same configurations as those of the second embodiment, and the description thereof may be omitted.

FIGS. 27A and 27B are cross-sectional views along an X direction illustrating an example of a configuration of the semiconductor memory device 2a according to the first modification of the second embodiment. More specifically, FIG. 27A is a cross-sectional view along an X direction illustrating an example of a configuration of a contact region ERw of the first modification. FIG. 27B is an enlarged cross-sectional view of the columnar portion HRw of the first modification.

As illustrated in FIGS. 27A and 27B, the semiconductor memory device 2a of the first modification includes a plurality of columnar portions HRw. Similarly to the second embodiment described above, these columnar portions HRw include the plurality of flange portions FL. In addition, the columnar portions HRw include the insulating layers 54w that cover the side walls and the bottom surfaces. Similarly to the insulating layers 54w described above, the insulating layers 54w are, for example, silicon oxide layers containing at least one of carbon and nitrogen, and have at least one of a higher Young's modulus, a lower compressive stress, and a higher tensile stress than the insulating layer OL of the stacked body LM4.

In other words, in the semiconductor memory device 2a of the first modification, it can be considered that the insulating layers OLc covering the columnar portions HR and including the plurality of flange portions FL are provided around the columnar portions HR of the first embodiment described above. At this time, the columnar portion HR can also be regarded as corresponding to the core material of the columnar portion HRw having the insulating layer 54w.

FIGS. 28A and 28B are views illustrating a part of a procedure of a method for manufacturing the semiconductor memory device 2a according to the first modification of the second embodiment. More specifically, FIGS. 28A and 28B illustrate a cross section along the X direction of the semiconductor memory device 2a in the middle of manufacturing, including a region that later becomes the memory region MR and a region that later becomes the contact region ERw.

FIG. 28A is the same as the state illustrated in FIG. 25B of the second embodiment described above. That is, the plurality of flange-shaped gap layers GPf is formed on the side walls of the plurality of holes HL, and the insulating layers 54w are formed on the side walls and the bottom surfaces thereof.

As illustrated in FIG. 28B, in the method for manufacturing the semiconductor memory device 2a according to the first modification, the holes HL are filled with the insulating layers 54 without removing the insulating layers 54w on the side walls and the bottom surfaces in the holes HL. As a result, the columnar portions HRw of the first modification are formed.

The subsequent processes are performed in the same manner as in the second embodiment described above.

With the semiconductor memory device 2 of the first modification, the plurality of columnar portions HRW includes a side wall extending in the stacking direction and having at least one of a higher Young's modulus, a lower compressive stress, and a higher tensile stress than the plurality of insulating layers OL. Also with such a configuration, it is possible to suppress the bending of the insulating layers OL at the time of the replacement treatment.

With the semiconductor memory device 2a of the first modification, the same effects as those of the semiconductor memory device 2 of the second embodiment described above are obtained.

### Second Modification

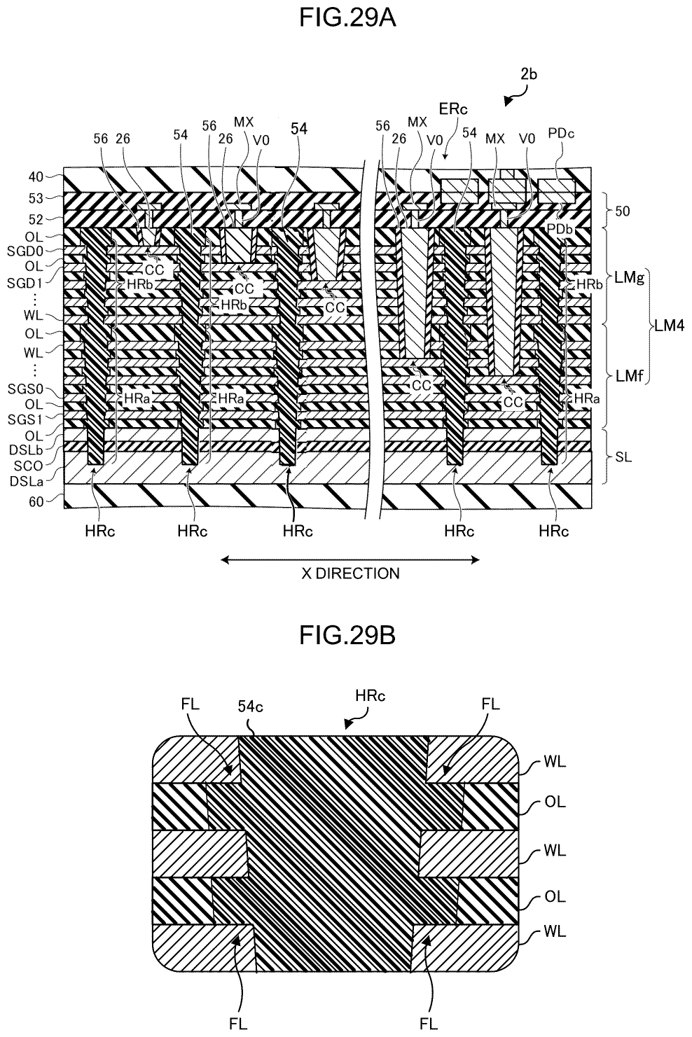

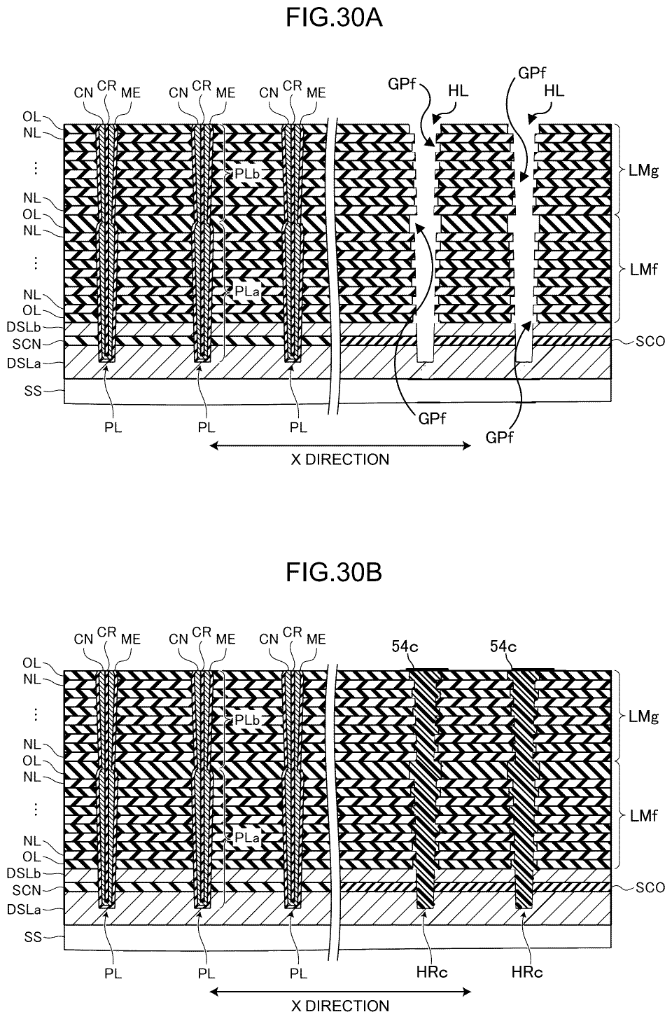

Next, a semiconductor memory device 2b of a second modification of the second embodiment will be described with reference to FIGS. 29A to 30B. The semiconductor memory device 2b of the second modification is different from the semiconductor memory device of the above-described second embodiment in that the semiconductor memory device 2b includes columnar portions HRc having a high Young's modulus or the like as a whole.

In the drawings described below, the same reference numerals are given to the same configurations as those of the second embodiment, and the description thereof may be omitted.

FIGS. 29A and 29B are cross-sectional views along an X direction illustrating an example of a configuration of the semiconductor memory device 2b according to the first modification of the second embodiment. More specifically, FIG. 29A is a cross-sectional view along an X direction illustrating an example of a configuration of a contact region ERc of the second modification. FIG. 29B is an enlarged cross-sectional view of the columnar portion HRc of the second modification.

As illustrated in FIGS. 29A and 29B, the semiconductor memory device 2b of the second modification includes the plurality of columnar portions HRc. Similarly to the second embodiment described above, these columnar portions HRc include the plurality of flange portions FL. In addition, the main body portion of the columnar portion HRc also includes an insulating layer 54c having at least one of a higher Young's modulus, a lower compressive stress, and a higher tensile stress than the insulating layer OL of the stacked body LM4, similarly to the plurality of flange portions FL. That is, the insulating layer 54c is, for example, a silicon oxide layer containing at least one of carbon and nitrogen.

FIGS. 30A and 30B are views illustrating a part of a procedure of a method for manufacturing the semiconductor memory device 2b according to the second modification of the second embodiment. More specifically, FIGS. 30A and 30B illustrate a cross section along the X direction of the semiconductor memory device 2b in the middle of manufacturing, including a region that later becomes the memory region MR and a region that later becomes the contact region ERc.

FIG. 30A is the same as the state illustrated in FIG. 24B of the second embodiment described above. That is, a state in which a chemical liquid or the like is injected through the plurality of holes HL, or CDE or the like is used so that the plurality of insulating layers OL exposed on the side walls of the plurality of holes HL is retracted is illustrated. Accordingly, the plurality of flange-shaped gap layers GPf is provided on the side walls of the plurality of holes HL.

As illustrated in FIG. 30B, the holes HL are filled with the insulating layers 54c. As a result, the plurality of columnar portions HRc is formed.

The subsequent processes are performed in the same manner as in the second embodiment described above.

With the semiconductor memory device 2b of the second modification, the plurality of columnar portions HRC includes the same type of material as the plurality of flange portions FL. Also with such a configuration, it is possible to suppress the bending of the insulating layers OL at the time of the replacement treatment.

With the semiconductor memory device 2b of the second modification, the same effects as those of the semiconductor memory device 2 of the second embodiment described above are obtained.

### Third Modification

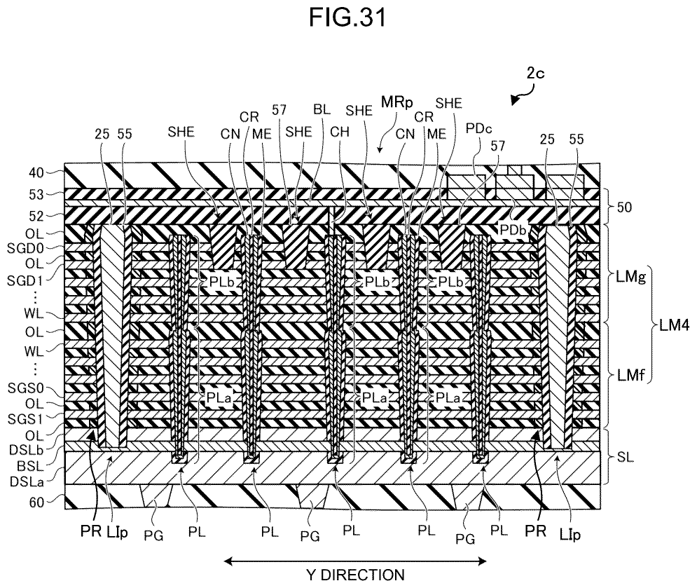

Next, a semiconductor memory device 2c of a third modification of the second embodiment will be described with reference to FIG. 31. The semiconductor memory device 2c of the third modification is different from the semiconductor memory device of the above-described second embodiment in that, for example, insulating layers having a high Young's modulus are disposed around plate-like contacts LI.

In the drawings described below, the same reference numerals are given to the same configurations as those of the second embodiment, and the description thereof may be omitted.

FIG. 31 is a cross-sectional view along an X direction illustrating an example of a configuration of the semiconductor memory device 2c according to the third modification of the second embodiment. More specifically, FIG. 31 is a cross-sectional view along an X direction illustrating an example of a configuration of a memory region MRp of the third modification.

As illustrated in FIG. 31, the semiconductor memory device 2c of the third modification includes a plurality of plate-like contacts LIp. The plate-like contact LIp includes a plurality of protrusions PR extending from the side wall portion of the plate-like contact LIp toward the insulating layer OL side at the height positions of the plurality of insulating layers OL of the stacked body LM4. The plurality of protrusions PR is, for example, a silicon oxide layer containing at least one of carbon and nitrogen, and has at least one of a higher Young's modulus, a lower compressive stress, and a higher tensile stress than the insulating layer OL of the stacked body LM4.

The protrusions PR provided on the plate-like contact LIp can also be formed, for example, in the same manner as the flange portions FL of the columnar portion HRf of the second embodiment described above. That is, after the slit ST is formed, the insulating layer OL exposed on the side wall of the slit ST is retracted at a predetermined timing. In addition, an insulating layer such as a silicon oxide layer containing at least one of carbon and nitrogen is formed on the side wall of the slit ST using ALD, LP-CVD, or the like. At this time, the insulating layer may be selectively formed in the gap layer of the side wall of the slit ST generated as a result of the retreat of the insulating layer OL by combining ALD, LP-CVD, or the like and the selective growth method. When the insulating layer is formed on the entire side wall of the slit ST, the insulating layer is removed from the side wall of the slit ST. Thus, the above-described protrusions PR are formed.

As described above, the columnar portions HR and the like of the first embodiment described above are disposed in the contact region ER while avoiding interference with the plate-like contacts LI in addition to the contacts CC. For this reason, the disposition density of the columnar portions HR is reduced also around the plate-like contacts LI, and the insulating layer OL is easily bent.

With the semiconductor memory device 2c of the third modification, the plate-like contacts LIp include the plurality of protrusions PR protruding from the side walls on both sides in the Y direction to the plurality of insulating layers OL at the height positions of the plurality of insulating layers OL. In other words, the plurality of insulating layers OL has at least one of a higher Young's modulus, a lower compressive stress, and a higher tensile stress than the other portions within a predetermined distance from the portion in contact with the above-described plate-like contacts LI excluding the protrusions PR toward the plurality of columnar portions HR. As a result, the bending of the insulating layer OL can be suppressed even in the region between the plate-like contacts LIp and the middle general portions HR.

### Third Embodiment

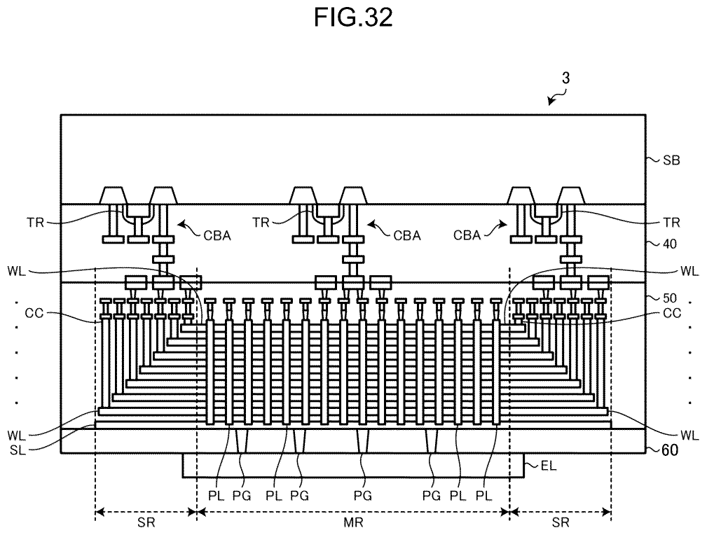

In the first and second embodiments and the modifications thereof described above, for example, in the contact region ER, the plurality of contacts CC penetrates the stacked body LM and is connected to connection target word lines WL or the like. However, for example, as in a semiconductor memory device 3 illustrated in FIG. 32, a stacked body including staircase regions SR in which word lines WL and the like are processed in a staircase shape may be formed, and contacts CC may be connected to word lines WL constituting terrace surfaces of the staircase regions SR. Also in this case, the staircase regions SR may be disposed at end portions or a central portion of the stacked body in the X direction.

In this manner, in a case where the word lines WL are processed in a staircase shape and connected to the contacts CC, the contacts CC can be formed by forming contact holes reaching the terrace surfaces of the word lines WL and filling the contact holes with conductive layers.

However, the method for forming the contacts CC in the staircase regions SR is not limited to the above, and for example, through-holes penetrating the stacked body can be formed at positions overlapping the terrace surfaces of the staircase regions SR in an up-down direction, and the contacts CC can be formed inside the through-holes. In the case of adopting such a method, it is also possible to apply the configurations of the columnar portions HRf, HRW, HRc, and the like described in the second embodiment and the modifications described above to the contacts CC. Hereinafter, such contacts CCf, CCw, and CCc will be described in detail in first to third modifications.

### First Modification

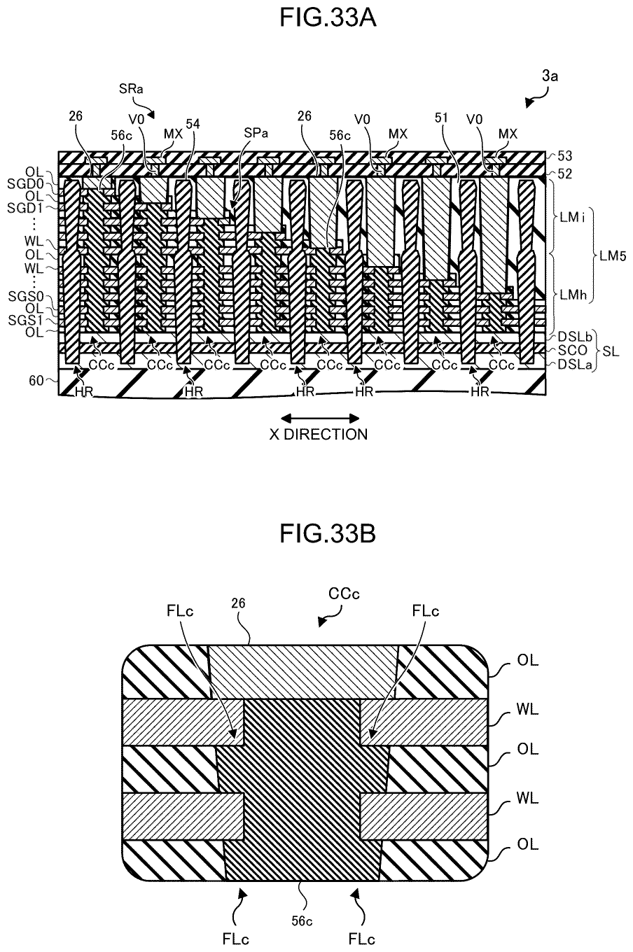

Hereinafter, a semiconductor memory device 3a of a first modification will be described with reference to FIGS. 33A to 37D. The semiconductor memory device 3a of the first modification includes contacts CCc to which the configuration of the columnar portion HRc of the second modification of the second embodiment described above is applied.

In the drawings described below, the same reference numerals are given to the same configurations as those of the first and second embodiments, and the description thereof may be omitted.

FIGS. 33A and 33B are cross-sectional views along the X direction illustrating an example of a configuration of the semiconductor memory device 3a according to the first modification of the third embodiment. More specifically, FIG. 33A is a cross-sectional view along the X direction illustrating an example of a configuration of a staircase region SRa provided in the semiconductor memory device 3a of the first modification. FIG. 33B is an enlarged cross-sectional view of the contact CCc of the first modification.

As illustrated in FIGS. 33A and 33B, the semiconductor memory device 3a of the first modification includes a stacked body LM5 including stacked bodies LMh and LMi. Each of the stacked bodies LMh and LMi has a configuration in which a plurality of word lines WL and the like and insulating layers OL are alternately stacked one by one.

In addition, the stacked body LM5 of the first modification includes the staircase regions SRa at both end portions in the X direction, for example. The staircase region SRa includes staircase portions SPa in which the plurality of word lines WL and select gate lines SGD and SGS are processed in a staircase shape. However, in FIG. 33A, a portion in which select gate lines SGS0 and SGS1, which are lower layer portions of the stacked body LM5, are processed in a staircase shape is omitted.

The contacts CCc are disposed at positions overlapping the terrace surfaces of the staircase portions SPa in the up-down direction, and the individual word lines WL and the like are connected to portions processed in a staircase shape.

More specifically, the individual contacts CCc penetrate an insulating layer 51, the corresponding terrace surfaces of the staircase portions SPa, and the stacked body LM5 below the terrace surfaces at positions overlapping the terrace surfaces in the up-down direction, and reach a source line SL.

In addition, the contact CCc includes, from the upper surface of the insulating layer 51, a conductive layer 26 that reaches the word line WL or the like processed in a staircase shape on the terrace surface of the staircase portion SPa and an insulating layer 56c that reaches the lower end portion of the contact CCc from the lower end portion of the conductive layer 26. The conductive layer 26 is a tungsten layer, a copper layer, or the like, and the insulating layer 56c is an insulating layer having at least one of a higher Young's modulus, a lower compressive stress, and a higher tensile stress than the insulating layer OL of the stacked body LM5, and is, for example, a silicon oxide layer or the like containing at least one of carbon and nitrogen.

In addition, the insulating layer 56c penetrating the stacked body LM5 in the staircase portion SPa includes a core material portion having a diameter smaller than that of the conductive layer 26 in the upper portion of the contact CCc and a plurality of flange portions FLc protruding outward at the height positions of the individual insulating layers OL of the stacked body LM5. Note that the diameter including the flange portions FLc of the insulating layer 56c is substantially equal to the diameter of the conductive layer 26.

With the above configuration, each contact CCc is connected to the word line WL or the like processed in a staircase shape on the terrace surface of the staircase portion SPa at the lower end portion of the conductive layer 26. In addition, the strength of the stacked body LM5 at the time of replacement is maintained by the insulating layer 56c included in each contact CCc and penetrating the stacked body LM5 in the staircase portion SPa.

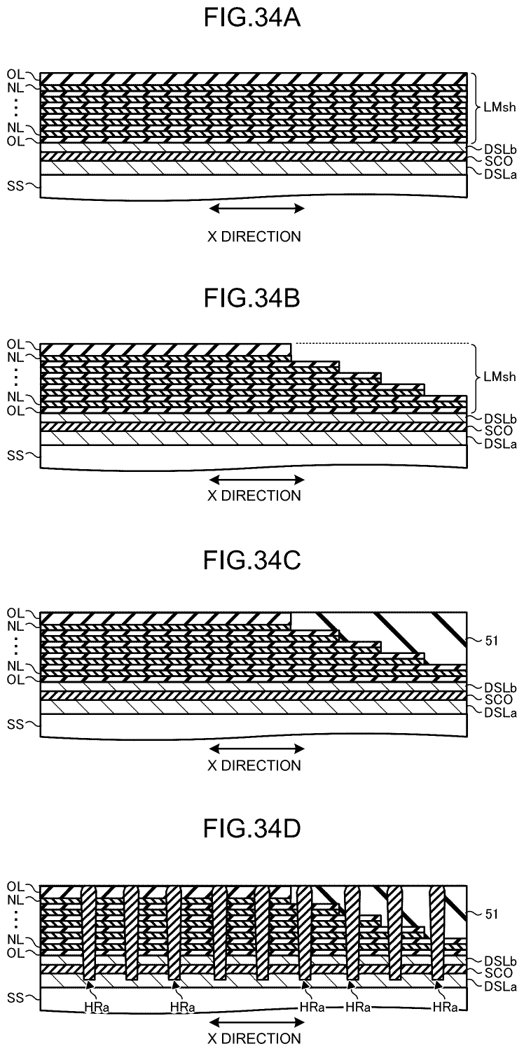

Next, a method for manufacturing the semiconductor memory device 3a of the first modification will be described with reference to FIGS. 34A to 37D. FIGS. 34A to 37D are views sequentially illustrating a part of a procedure of the method for manufacturing the semiconductor memory device 3a according to the first modification of the third embodiment.

More specifically, FIGS. 34A to 37D are cross-sectional views along the X direction of the staircase region SRa of the semiconductor memory device 3a in the middle of manufacturing. In FIGS. 34A to 37D described below, a method for forming the contacts CCc will be mainly described.

As illustrated in FIG. 34A, a stacked body LMsh in which a plurality of insulating layers NL and a plurality of insulating layers OL are alternately stacked one by one is formed above the source line SL. The stacked body LMsh is a portion that becomes the stacked body LMh by the subsequent replacement.

As illustrated in FIG. 34B, in a part of the stacked body LMsh, for example, each pair of the insulating layers NL and OL is processed in a staircase shape. Such a staircase shape is formed, for example, by forming a photoresist layer or the like covering the upper surface of the stacked body LMsh and repeating slimming of the photoresist layer and etching removal of the insulating layers NL and OL exposed from the photoresist layer a plurality of times.

As illustrated in FIG. 34C, a portion of the stacked body LMsh processed in a staircase shape is covered with the insulating layer 51 reaching the upper surface height of an unprocessed portion of the stacked body LMsh.

As illustrated in FIG. 34D, holes penetrating the stacked body LMsh are formed, and are filled with insulating layers 54 and the like to form a plurality of columnar portions HRa. Note that, as described above, in parallel with these columnar portions HRa, the pillars PLS (see FIG. 4C and the like) that are filled with sacrificial layers such as amorphous silicon layers and later become lower structures of the pillars PL may be formed.

However, the formation of the stair shape in the stacked body LMsh and the formation of the pillars PLs and the columnar portions HRa can be switched in the treatment order. That is, the pillars PLs and the columnar portions HRa may be first formed in the stacked body LMsh, and then the stair shape may be formed. In this case, when the stacked body LMsh is processed in a staircase shape, the columnar portions HRa above the terrace surfaces of the stacked body LMsh are etched away together with the insulating layers NL and OL.

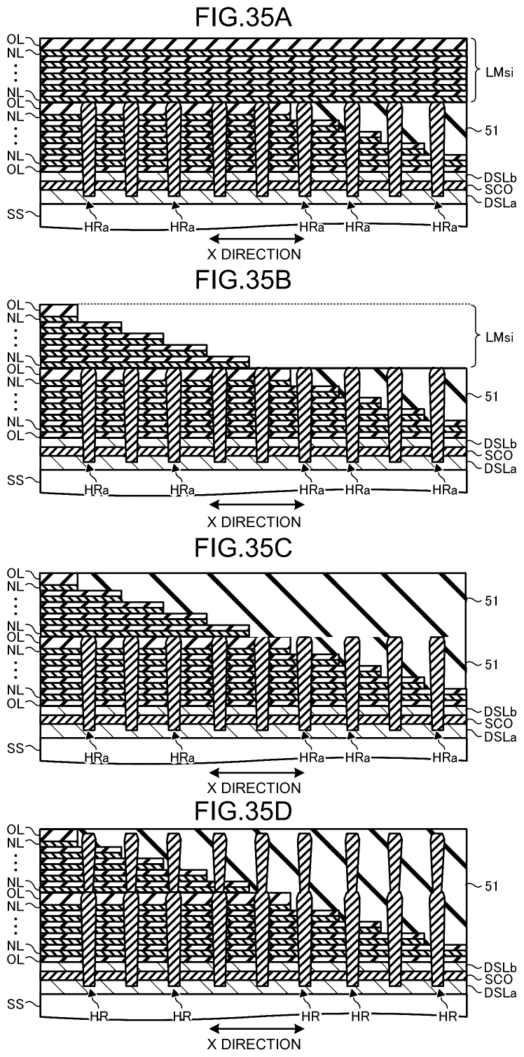

As illustrated in FIG. 35A, a stacked body LMsi in which a plurality of insulating layers NL and a plurality of insulating layers OL are alternately stacked one by one is formed above the stacked body LMsh. The stacked body LMsi is a portion that becomes the stacked body LMi by the subsequent replacement.

As illustrated in FIG. 35B, in a part of the stacked body LMsi, for example, each pair of the insulating layers NL and OL is processed in a staircase shape. Such a stair shape can also be formed in the same manner as described above. That is, a photoresist layer or the like covering the upper surface of the stacked body LMsi is formed, and slimming of the photoresist layer and etching removal of the insulating layers NL and OL exposed from the photoresist layer are repeated a plurality of times.

As illustrated in FIG. 35C, a portion of the stacked body LMsi processed in a staircase shape and the portion of the stacked body LMsh covered with the insulating layer 51 are further covered with the insulating layer 51 reaching the upper surface height of an unprocessed portion of the stacked body LMsi.

As illustrated in FIG. 35D, holes penetrating the stacked body LMsi and connected to the upper end portions of the individual columnar portions HRa are formed and filled with the insulating layers 54 or the like to form a plurality of columnar portions HR penetrating the stacked bodies LMsh and LMsi. Note that, as described above, a plurality of pillars PL may be formed in parallel with the columnar portions HR.

However, the formation of the stair shape in the stacked body LMsi and the formation of the pillars PL and the columnar portions HR can be switched in the treatment order. That is, the pillars PL and the columnar portions HR may be first formed in the stacked body LMsi, and then the stair shape may be formed. In this case, when the stacked body LMsi is processed in a staircase shape, the columnar portions HR above the terrace surfaces of the stacked body LMsi are etched away together with the insulating layers NL and OL.

As described above, a staircase shape is formed in the stacked bodies LMsh and LMsi, and the columnar portions HR penetrating the stacked bodies LMsh and LMsi are formed. Note that, in the subsequent drawings, these columnar portions HR are omitted.

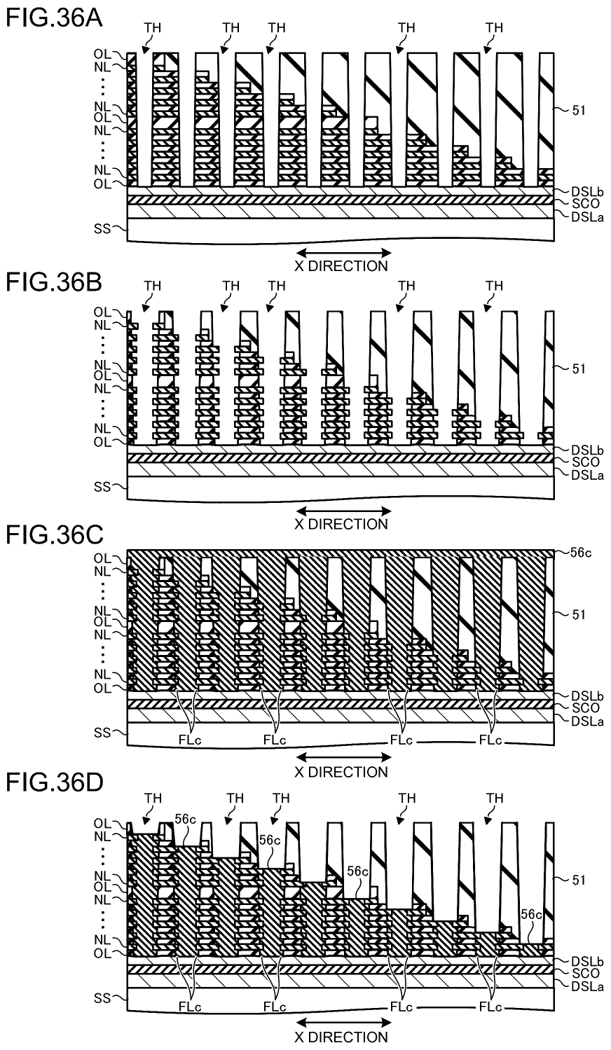

As illustrated in FIG. 36A, through-holes TH penetrating the insulating layer 51 and the stacked bodies LMsh and LMsi and reaching the source line SL are formed at positions overlapping the terrace surfaces of the staircase parts of the stacked bodies LMsh and LMsi in the up-down direction.

As illustrated in FIG. 36B, a chemical liquid for dissolving the insulating layers OL is injected into the through-holes TH. As a result, the insulating layers OL exposed on the side walls of the through-holes TH retreat from the side walls of the through-holes TH toward the outside of the through-holes TH. At this time, the retreat amount of the insulating layers OL in the outer peripheral portions of the through-holes TH is substantially the same in all directions.

Note that the treatment illustrated in FIG. 36B may be formed by a method other than wet etching such as a chemical dry etching method.

Here, as described above, when the contacts CC are formed in the through-holes TH penetrating the stacked body LM5, the conductive layers 26 to be connected to the individual word lines WL and the like are formed above the through-holes TH, and the insulating layers such as silicon oxide layers are loaded into the lower portions of the through-holes TH.

However, in the semiconductor memory device 3a of the first modification, as described below, the insulating layer 56c having at least one of a higher Young's modulus, a lower compressive stress, and a higher tensile stress than the insulating layer OL of the stacked body LM5 is formed instead of the insulating layer such as the silicon oxide layer.

As illustrated in FIG. 36C, for example, silicon oxide layers or the like to which at least one of carbon and nitrogen is added are formed in the through-holes TH. As a result, the insulating layers 56c having the plurality of flange portions FLc protruding at the height positions of the insulating layers OL are formed. The insulating layer 56c is also formed on the upper surface of the stacked body LMsi.

As illustrated in FIG. 36D, the upper end portions of the insulating layers 56c loaded into the through-holes TH are removed. At this time, the insulating layer 56c on the upper surface of the stacked body LMsi is also removed. As a result, a plurality of through-holes TH penetrating the insulating layer 51 and reaching the portions of the individual insulating layers NL processed in a staircase shape is formed again at positions overlapping the individual terrace surfaces of the stacked bodies LMsh and LMsi in the up-down direction. However, the lower portions of the through-holes TH remain filled with the insulating layers 56c.

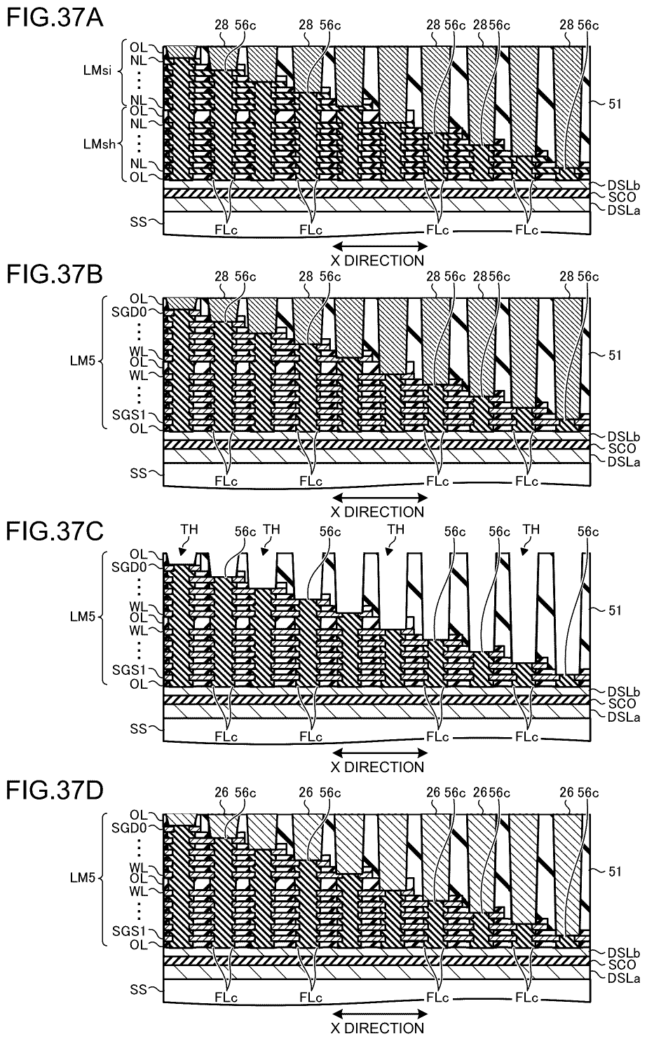

As illustrated in FIG. 37A, the through-holes TH are filled with sacrificial layers 28 such as amorphous silicon layers.

As illustrated in FIG. 37B, as described above, the stacked bodies LMsh and LMsi are replaced to form the stacked body LM5 in which the plurality of word lines WL and the like and the plurality of insulating layers OL are alternately stacked one by one.

As illustrated in FIG. 37C, the sacrificial layers 28 loaded in the through-holes TH are removed.

As illustrated in FIG. 37D, the conductive layers 26 are formed in the through-holes TH. As a result, the contacts CCc connected to the individual word lines WL and the like are formed.

Note that, the other configurations are formed in the same manner as in the first and second embodiments and the like described above.

Thus, the semiconductor memory device 3a of the first modification is manufactured.

With the semiconductor memory device 3a of the first modification, the contact CCc has, from above the staircase portion SPa, an upper structure including the conductive layer 26 that reaches and is connected to the word line WL processed in a staircase shape and a lower structure including the insulating layer 56c extending in the stacked bodies LMh and LMi from the lower end portion of the conductive layer 26. As a result, it is possible to suppress the bending of the insulating layers OL at the time of the replacement treatment.

### Second Modification

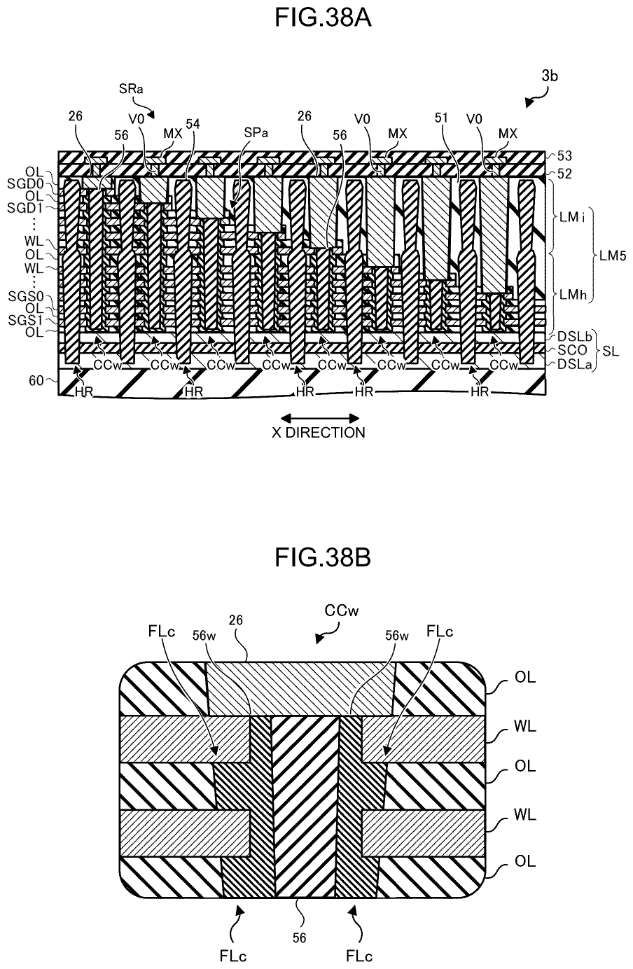

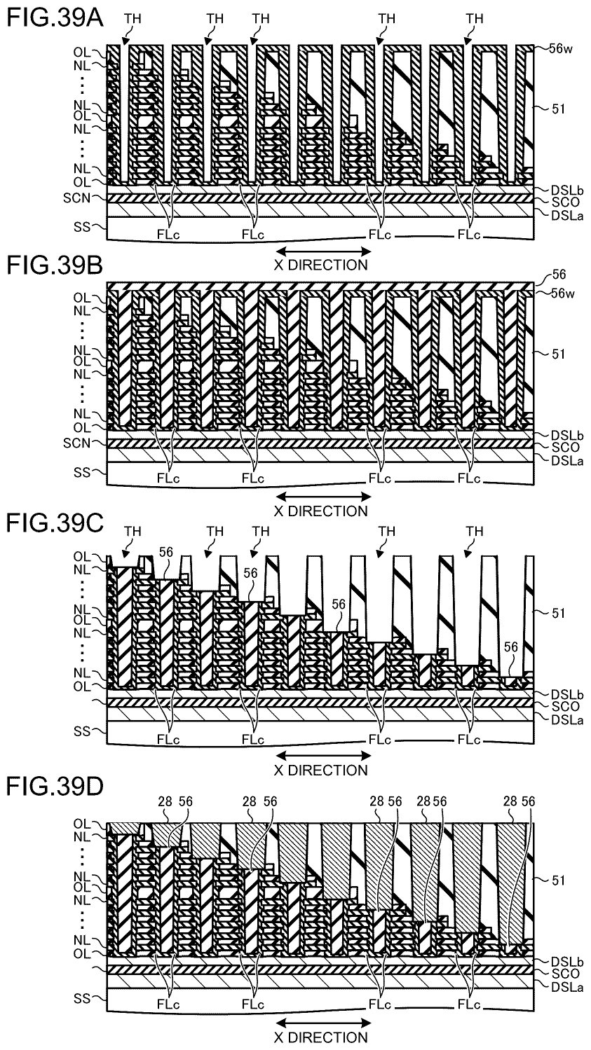

Next, a semiconductor memory device 3b of a second modification will be described with reference to FIGS. 38A to 39D. The semiconductor memory device 3b of the second modification includes contacts CCw to which the configuration of the columnar portion HRw of the first modification of the second embodiment described above is applied.

In the drawings described below, the same reference numerals are given to the same configurations as those of the first and second embodiments, and the description thereof may be omitted.

FIGS. 38A and 38B are cross-sectional views along the X direction illustrating an example of a configuration of the semiconductor memory device 3b according to the second modification of the third embodiment. More specifically, FIG. 38A is a cross-sectional view along the X direction illustrating an example of a configuration of a staircase region SRa provided in the semiconductor memory device 3b of the second modification. FIG. 38B is an enlarged cross-sectional view of the contact CCw of the second modification.

However, in FIG. 38A, a portion in which select gate lines SGS0 and SGS1, which are lower layer portions of the stacked body LM5, are processed in a staircase shape is omitted.

As illustrated in FIGS. 38A and 38B, in the semiconductor memory device 3b of the second modification, the contacts CCw are disposed at positions overlapping the terrace surfaces of the staircase portions SPa in the up-down direction, and the individual word lines WL and the like are connected to portions processed in a staircase shape.

The contact CCw of the second modification includes, from the upper surface of the insulating layer 51, a conductive layer 26 that reaches the word line WL or the like processed in a staircase shape on the terrace surface of the staircase portion SPa and an insulating layer 56 that extends downward from the lower end portion of the conductive layer 26. The conductive layer 26 is a tungsten layer, a copper layer, or the like, and the insulating layer 56 is, for example, a silicon oxide layer or the like, similarly to the insulating layer OL of the stacked body LM5.

The insulating layer 56 has a diameter smaller than that of the conductive layer 26 in the upper portion of the contact CCw. In addition, the side wall and the lower end portion of the insulating layer 56 are covered with an insulating layer 56w including a plurality of flange portions FLc protruding to the plurality of insulating layers OL at the height positions of the plurality of insulating layers OL. These flange portions FLc and insulating layer 56w are, for example, silicon oxide layers containing at least one of carbon and nitrogen, and have at least one of a higher Young's modulus, a lower compressive stress, and a higher tensile stress than the plurality of insulating layers OL.

Also with the above configuration, each contact CCw is connected to the word line WL or the like processed in a staircase shape on the terrace surface of the staircase portion SPa at the lower end portion of the conductive layer 26. In addition, the strength of the stacked body LM5 at the time of replacement is maintained by the insulating layer 56w covering the insulating layer 56 penetrating the stacked body LM5 in each contact CCw.

Next, a method for manufacturing the semiconductor memory device 3b of the second modification will be described with reference to FIGS. 39A to 39D. FIGS. 39A to 39D are views sequentially illustrating a part of a procedure of the method for manufacturing the semiconductor memory device 3b according to the second modification of the third embodiment.

More specifically, FIGS. 39A to 39D are cross-sectional views along the X direction of the staircase region SRa of the semiconductor memory device 3b in the middle of manufacturing. In FIGS. 39A to 39D described below, a method for forming the contacts CCw will be mainly described.

When the contacts CCw of the second modification are formed, treatment similar to that in FIGS. 34A to 36B of the first modification described above is performed. As a result, a plurality of through-holes TH enlarged in diameter at the height positions of the insulating layers OL by the wet treatment is formed in the staircase parts of the stacked bodies LMsh and LMsi.

As illustrated in FIG. 39A, in the treatment for forming the contacts CCw of the second modification, insulating layers such as silicon oxide layers are formed on the side walls and the bottom surfaces of the through-holes TH while adding at least one of carbon and nitrogen using, for example, an ALD method or the like.

As a result, the insulating layer 56w having the flange portions FLc at the height positions of the insulating layers OL and covering the side walls and the bottom surfaces of the through-holes TH is formed. At this time, the insulating layer 56w is also formed on the upper surface of the stacked body LMsi. In addition, at this time, the through-holes TH are still in a state of having a gap penetrating the stacked bodies LMsh and LMsi in the central portion.

As illustrated in FIG. 39B, the gaps of the through-holes TH remaining inside the insulating layer 56w are filled with the insulating layer 56 such as a silicon oxide layer. At this time, the insulating layer 56 is also formed on the upper surface of the stacked body LMsi via the insulating layer 56w.

As illustrated in FIG. 39C, the upper end portion of the insulating layer 56 loaded in the through-holes TH and the insulating layer 56w covering the side walls of the upper portions of the through-holes TH are removed. At this time, the insulating layers 56 and 56w on the upper surface of the stacked body LMsi are also removed. As a result, a plurality of through-holes TH penetrating the insulating layer 51 and reaching the portions of the individual insulating layers NL processed in a staircase shape is formed again at positions overlapping the individual terrace surfaces of the stacked bodies LMsh and LMsi in the up-down direction. However, the insulating layers 56w and 56 remain in the lower portions of the through-holes TH.

As illustrated in FIG. 39D, the through-holes TH are filled with sacrificial layers 28 such as amorphous silicon layers.

Thereafter, treatment similar to that in FIGS. 37B to 37D of the first modification described above is performed, and the contacts CCw of the second modification are formed. In addition, the other configurations are formed in the same manner as in the first and second embodiments and the like described above.

Thus, the semiconductor memory device 3b of the second modification is manufactured.

With the semiconductor memory device 3b of the second modification, the contact CCw includes the core material of the insulating layer 56 extending in the stacked body LM5 in the stacking direction, and the side wall of the insulating layer 56w extending in the stacking direction of the stacked body LM5 and having at least one of a higher Young's modulus, a lower compressive stress, and a higher tensile stress than the plurality of insulating layers OL. Also with such a configuration, it is possible to suppress the bending of the insulating layers OL at the time of the replacement treatment.

### Third Modification

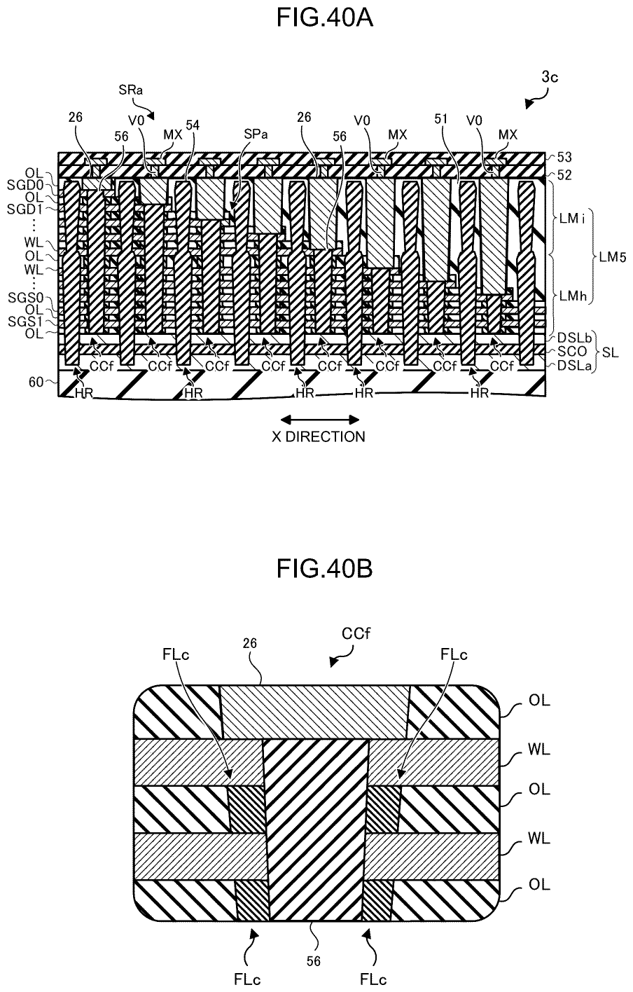

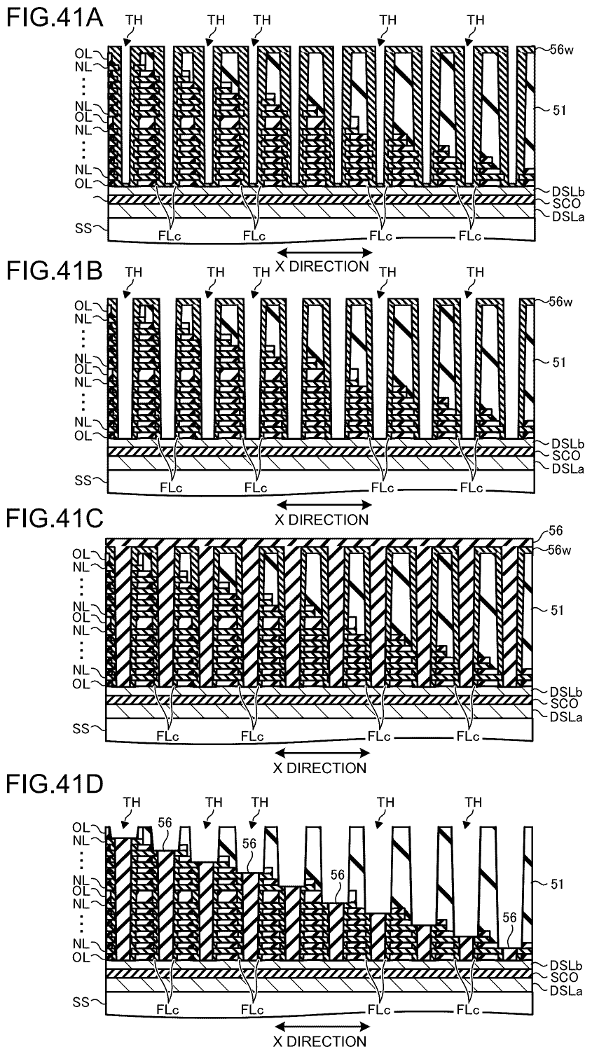

Next, a semiconductor memory device 3c of a third modification will be described with reference to FIGS. 40A to 41D. The semiconductor memory device 3c of the third modification includes contacts CCf to which the configuration of the columnar portion HRf of the second embodiment described above is applied.

In the drawings described below, the same reference numerals are given to the same configurations as those of the first and second embodiments, and the description thereof may be omitted.

FIGS. 40A and 40B are cross-sectional views along the X direction illustrating an example of a configuration of the semiconductor memory device 3c according to the third modification of the third embodiment. More specifically, FIG. 40A is a cross-sectional view along the X direction illustrating an example of a configuration of a staircase region SRa provided in the semiconductor memory device 3c of the third modification. FIG. 40B is an enlarged cross-sectional view of the contact CCf of the third modification.

However, in FIG. 40A, a portion in which select gate lines SGS0 and SGS1, which are lower layer portions of the stacked body LM5, are processed in a staircase shape is omitted.

As illustrated in FIGS. 40A and 40B, in the semiconductor memory device 3c of the third modification, the contacts CCf are disposed at positions overlapping the terrace surfaces of the staircase portions SPa in the up-down direction, and the individual word lines WL and the like are connected to portions processed in a staircase shape.

The contact CCf of the third modification includes, from the upper surface of the insulating layer 51, a conductive layer 26 that reaches the word line WL or the like processed in a staircase shape on the terrace surface of the staircase portion SPa and an insulating layer 56 that reaches the lower end portion of the contact CCf from the lower end portion of the conductive layer 26. The conductive layer 26 is a tungsten layer, a copper layer, or the like, and the insulating layer 56 is a silicon oxide layer or the like.

The insulating layer 56 has a diameter smaller than that of the conductive layer 26 in the upper portion of the contact CCf. In addition, from the side wall of the insulating layer 56, a plurality of flange portions FLC, which is, for example, silicon oxide layers containing at least one of carbon and nitrogen, protrudes to the plurality of insulating layers OL at the height positions of the plurality of insulating layers OL. As a result, these flange portions FLc have at least one of a higher Young's modulus, a lower compressive stress, and a higher tensile stress than the plurality of insulating layers OL.

Also with the above configuration, each contact CCf is connected to the word line WL or the like processed in a staircase shape on the terrace surface of the staircase portion SPa at the lower end portion of the conductive layer 26. In addition, the strength of the stacked body LM5 at the time of replacement is maintained by the flange portions FLc protruding from the insulating layer 56 penetrating the stacked body LM5 in each contact CCf.

Next, a method for manufacturing the semiconductor memory device 3c of the third modification will be described with reference to FIGS. 41A to 41D. FIGS. 41A to 41D are views sequentially illustrating a part of a procedure of the method for manufacturing the semiconductor memory device 3c according to the third modification of the third embodiment.

More specifically, FIGS. 41A to 41D are cross-sectional views along the X direction of the staircase region SRa of the semiconductor memory device 3c in the middle of manufacturing. In FIGS. 41A to 41D described below, a method for forming the contacts CCf will be mainly described.

When the contacts CCf of the third modification are formed, treatment similar to that in FIGS. 34A to 36B of the first modification described above is performed. As a result, a plurality of through-holes TH enlarged in diameter at the height positions of the insulating layers OL by the wet treatment is formed in the stair-shaped parts of the stacked bodies LMsh and LMsi.

In addition, when the contacts CCf of the third modification are formed, treatment similar to that in FIG. 39A of the second modification described above is performed. As a result, the insulating layer 56w covering the side walls and the bottom surfaces of the through-holes TH and having the plurality of flange portions FLc is formed. This state is illustrated in FIG. 41A.

As illustrated in FIG. 41B, the insulating layer 56w is removed from the end surfaces of the plurality of insulating layers NL facing the side surfaces of the through-holes TH. As a result, the end surfaces of the plurality of insulating layers NL are exposed in the through-holes TH, and the insulating layer 56w is removed from the bottom surfaces of the through-holes TH.

As illustrated in FIG. 41C, gaps of the through-holes TH remaining inside the insulating layer 56w are filled with the insulating layer 56 such as a silicon oxide layer.

As illustrated in FIG. 41D, the upper end portion of the insulating layer 56 loaded in the through-holes TH and the insulating layer 56w covering the side walls of the upper portions of the through-holes TH are removed. As a result, a plurality of through-holes TH penetrating the insulating layer 51 and reaching the portions of the individual insulating layers NL processed in a staircase shape is formed again at positions overlapping the individual terrace surfaces of the stacked bodies LMsh and LMsi in the up-down direction. However, the lower portions of the through-holes TH are filled with the insulating layer 56, and a state in which the plurality of flange portions FLc protrudes from the insulating layer 56 is maintained.

Thereafter, the through-holes TH are filled with the sacrificial layers 28 such as amorphous silicon layers, and treatment similar to that in FIGS. 37B to 37D of the first modification described above is performed to form the contacts CCf of the third modification. In addition, the other configurations are formed in the same manner as in the first and second embodiments and the like described above.

Thus, the semiconductor memory device 3c of the third modification is manufactured.

With the semiconductor memory device 3c of the third modification, the contact CCf includes the plurality of flange portions FLc each protruding to the plurality of insulating layers OL at the height positions of the plurality of insulating layers OL and having at least one of a higher Young's modulus, a lower compressive stress, and a higher tensile stress than the plurality of insulating layers OL. Also with such a configuration, it is possible to suppress the bending of the insulating layers OL at the time of the replacement treatment.

Note that, in the third modification described above, the insulating layer 56w covering the entire side walls of the through-holes TH is formed, and then the flange portions FLc obtained by thinning the insulating layer 56w are formed. However, the insulating layer 56w that fills only the flange portion FLc parts may be selectively formed. In this case, for example, a gas preferentially adsorbed to the insulating layers OL can be used as the film-forming gas. Alternatively, inhibitor layers that inhibit the formation of the insulating layer 56w are formed on the insulating layers NL, and then the insulating layer 56w is formed.

### Other Embodiments

In the first and second embodiments and the modifications thereof described above, the insulating layers OLc or the like having at least one of high Young's modulus, low compressive stress, and high tensile stress contain, for example, at least one of carbon and nitrogen. However, such insulating layers OLc may contain metal or the like. That is, the insulating layers OLc may be metal oxide layers or the like. The metal oxide layer may contain, for example, at least one of aluminum, zirconium, molybdenum, hafnium, and titanium as the metal contained.

In the first and second embodiments and the modifications thereof described above, the contact regions ER and the like are disposed at both end portions in the X direction of the stacked body LM. However, the disposition position of the contact region in the stacked body LM is not limited thereto. The contact region may be disposed, for example, in a central portion of the stacked body LM, and in this case, for example, the memory region MR can be disposed at both end portions of the stacked body LM.

In addition, in the first and second embodiments and the modifications thereof described above, the pillars PL are connected to the source line SL on the side surfaces of the channel layers CN, but it is not limited thereto. For example, the pillar may be configured to be connected to the source line at the lower end portion of the channel layer by removing the memory layer on the bottom surface of the pillar.

In addition, in the first and second embodiments and the modifications thereof described above, the columnar portions HR are configured solely by the insulating layers 54. However, the columnar portions HR may have, for example, the same layer structure as the pillars PL.

In addition, in the first and second embodiments and the modifications thereof described above, the insulating layers NL and OL are stacked in two times, and the stacked body LM having a two-tier structure including the stacked bodies LMa and LMb is provided. However, the stacked body may have a one-tier structure or a structure of three tiers or more. By increasing the number of tiers, the number of word lines WL stacked can be further increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of conductive layers and a plurality of insulating layers are alternately stacked;
a pillar that includes a channel layer extending through the stacked body in a stacking direction of the stacked body;
a contact that is provided in a region of the stacked body different from a disposition region of the pillar and connected to one conductive layer of the plurality of conductive layers; and
a plurality of columnar portions that is provided to be spaced apart a predetermined distance from the contact so as to surround the contact and extends through the stacked body in the stacking direction, wherein
an insulating layer of the plurality of insulating layers located in a region including the contact and surrounded by the plurality of columnar portions has, in at least a portion, at least one selected from the group consisting of a higher Young's modulus, a lower compressive stress, and a higher tensile stress than an insulating layer in the disposition region of the pillar.

2. The semiconductor memory device according to claim 1, wherein
the insulating layer of the plurality of insulating layers in a region where the contact is disposed has, over an entire region surrounded by the plurality of columnar portions, at least one selected from the group consisting of the higher Young's modulus, the lower compressive stress, and the higher tensile stress than the insulating layer in the disposition region of the pillar.

3. The semiconductor memory device according to claim 1, wherein
the insulating layer of the plurality of insulating layers in a region where the contact is disposed has, at least in a portion overlapping the contact in the stacking direction, at least one selected from the group consisting of the higher Young's modulus, the lower compressive stress, and the higher tensile stress than the insulating layer in the disposition region of the pillar.

4. The semiconductor memory device according to claim 1, wherein
the plurality of insulating layers has, within a predetermined distance from a portion in contact with the plurality of columnar portions toward outside of the plurality of columnar portions, at least one selected from the group consisting of the higher Young's modulus, the lower compressive stress, and the higher tensile stress than other portions.

5. The semiconductor memory device according to claim 1, further comprising:
a plate-like portion that extends in the stacked body in a first direction intersecting the stacking direction and in the stacking direction and divides the stacked body in a second direction intersecting the first direction and the stacking direction, wherein
the plurality of insulating layers has, within a predetermined distance from a portion in contact with the plate-like portion toward the plurality of columnar portions, at least one selected from the group consisting of the higher Young's modulus, the lower compressive stress, and the higher tensile stress than other portions.

6. The semiconductor memory device according to claim 1, wherein
the insulating layer having at least one selected from the group consisting of the high Young's modulus, the low compressive stress, and the high tensile stress contains at least one selected from the group consisting of carbon, nitrogen, and a metal.

7. The semiconductor memory device according to claim 6, wherein
the insulating layer having at least one selected from the group consisting of the high Young's modulus, the low compressive stress, and the high tensile stress contains 0.5 atom % or more of carbon.

8. The semiconductor memory device according to claim 6, wherein
the plurality of insulating layers includes a silicon oxide layer.

9. The semiconductor memory device according to claim 3, wherein
the insulating layer having at least one selected from the group consisting of the high Young's modulus, the low compressive stress, and the high tensile stress contains at least one selected from the group consisting of carbon and nitrogen as a dopant.

10. The semiconductor memory device according to claim 4, wherein
the insulating layer having at least one selected from the group consisting of the high Young's modulus, the low compressive stress, and the high tensile stress contains at least one selected from the group consisting of carbon, nitrogen, aluminum, zirconium, molybdenum, hafnium, and titanium.

11. A semiconductor memory device comprising:
a stacked body in which a plurality of conductive layers and a plurality of insulating layers are alternately stacked, the stacked body having a staircase portion in which the plurality of conductive layers is processed in a staircase shape;
a pillar that includes a channel layer extending through the stacked body in a stacking direction of the stacked body; and
a contact that is disposed in a region of the staircase portion overlapping, in the stacking direction, a portion where a first conductive layer of the plurality of conductive layers is processed in a staircase shape and is connected to the first conductive layer, wherein
the contact includes
from above the staircase portion, a first portion reaching the first conductive layer processed in the staircase shape and connected to the first conductive layer, the first portion being conductive, and
a second portion extending in the stacked body from a lower end portion of the first portion, and
the second portion includes
a plurality of flange portions each protruding to the plurality of insulating layers at height positions of the plurality of insulating layers and having at least one selected from the group consisting of a higher Young's modulus, a lower compressive stress, and a higher tensile stress than the plurality of insulating layers.

12. The semiconductor memory device according to claim 11, wherein
an outer edge portion of each of the plurality of flange portions is provided substantially concentrically with a side wall portion of the second portion at height positions of the plurality of conductive layers viewed from the stacking direction.

13. The semiconductor memory device according to claim 11, wherein
an outer edge portion of each of the plurality of flange portions is located at a position substantially equidistant from a center point of the second portion viewed from the stacking direction.

14. The semiconductor memory device according to claim 11, wherein
the second portion includes
a core material extending in the stacked body in the stacking direction, the core material being insulating, and
a side wall extending in the stacking direction and having at least one selected from the group consisting of a higher Young's modulus, a lower compressive stress, and a higher tensile stress than the plurality of insulating layers.

15. The semiconductor memory device according to claim 11, wherein
the second portion contains a same type of material as the plurality of flange portions throughout.

16. A semiconductor memory device comprising:
a stacked body in which a plurality of conductive layers and a plurality of insulating layers are alternately stacked;
a pillar that includes a channel layer extending through the stacked body in a stacking direction of the stacked body;
a contact that is provided in a region of the stacked body different from a disposition region of the pillar and connected to one conductive layer of the plurality of conductive layers; and
a plurality of columnar portions that is provided to be spaced apart a predetermined distance from the contact so as to surround the contact and extends through the stacked body in the stacking direction, wherein
the plurality of columnar portions includes a plurality of flange portions protruding to the plurality of insulating layers at height positions of the plurality of insulating layers and having at least one selected from the group consisting of a higher Young's modulus, a lower compressive stress, and a higher tensile stress than the plurality of insulating layers.

17. The semiconductor memory device according to claim 16, wherein
an outer edge portion of each of the plurality of flange portions is provided substantially concentrically with a side wall portion of each of the plurality of columnar portions at the height positions of the plurality of conductive layers viewed from the stacking direction.

18. The semiconductor memory device according to claim 16, wherein
an outer edge portion of each of the plurality of flange portions is located at a position substantially equidistant from a center point of each of the plurality of columnar portions viewed from the stacking direction.

19. The semiconductor memory device according to claim 16, wherein
each of the plurality of columnar portions includes
a core material extending in the stacked body in the stacking direction, the core material being insulating, and
a side wall extending in the stacking direction and having at least one selected from the group consisting of the higher Young's modulus, the lower compressive stress, and the higher tensile stress than the plurality of insulating layers.

20. The semiconductor memory device according to claim 16, wherein
the plurality of columnar portions contains a same type of material as the plurality of flange portions throughout.
